(19) United States
(12) Patent Application Publication
(10) Pub. No.: US 2024/0394454 A1
(43) Pub. Date: Nov. 28, 2024

(54) PATTERN MATCHING METHOD

(71) Applicant: ASML NETHERLANDS B.V., Veldhoven (NL)

(72) Inventors: Tsung-Pao FANG, Milpitas, CA (US); Wei-Chou LIN, San Jose, CA (US); Hao LIN, Redwood City, CA (US); Chao SONG, Sunnyvale, CA (US)

(73) Assignee: ASML NETHERLANDS B.V., Veldhoven (NL)

(21) Appl. No.: 18/695,261

(22) PCT Filed: Oct. 4, 2022
(86) PCT No.: PCT/EP2022/077591

§ 371 Date: Mar. 25, 2024

Related U.S. Application Data
(60) Provisional application No. 63/257,198, filed on Oct. 19, 2021.

(51) Int. Cl. G06F 30/392

(52) U.S. Cl. CPC G06F 30/392

(57) ABSTRACT

A method for grouping patterns associated with one or more design layouts of a semiconductor. The method involves obtaining a set of patterns (e.g., from one or more design layouts), where a pattern of the set of patterns includes a non-intersected feature portion (e.g., parallel bars) within a bounding box of the pattern. A non-intersected feature portion of a pattern is encoded to a pattern representation having elements, where each element has a first component indicating a type of an individual non-intersected feature portion, and a second component indicating a width of the individual non-intersected feature portion projected along a designated edge of an area enclosing the pattern. The set of patterns are grouped into one or more groups by comparing the pattern representations associated with the set of patterns.

### CROSS-REFERENCE TO RELATED APPLICATIONS

This application claims priority of U.S. application 63/257,198 which was filed on 19 Oct. 2021, and which is incorporated herein in its entirety by reference.

### TECHNICAL FIELD

The description herein relates generally to pattern matching, and more particularly, related to pattern selections based on patterning matching for computational lithography, metrology, model calibration or training related to a patterning process, other applications related the patterning process.

### BACKGROUND

A lithographic projection apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatuses, the pattern on the entire patterning device is transferred onto one target portion in one go; such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices as described herein can be gleaned, for example, from U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

### SUMMARY

In an embodiment, a method for grouping patterns associated with one or more design layouts of a semiconductor is described. The method involves obtaining a set of patterns (e.g., from one or more design layouts), where a pattern of the set of patterns includes a non-intersected feature portion (e.g., parallel bars) within a bounding box of the pattern. A non-intersected feature portion of a pattern is encoded to a pattern representation having elements, where each element has a first component indicating a type of an individual non-intersected feature portion, and a second component indicating a width of the individual non-intersected feature portion projected along a designated edge of an area enclosing the pattern. The set of patterns are grouped into one or more groups by comparing the pattern representations associated the set of patterns. In an embodiment, the method may further involve selecting a representative pattern from each group of the one or more groups for metrology measurements, or training models related to lithographic process.

In an embodiment, the grouping is based on exact pattern matching. In an embodiment, such grouping involves determining an exact pattern matching based on a comparison between the pattern representations of the set of patterns. For example, the grouping process involves comparing a first pattern representation associated with a first pattern of the set of patterns with a second pattern representation associated with the second pattern of the set of patterns; and responsive to a determination that the first pattern representation and the second pattern representation being the same, grouping the first pattern and the second pattern in a first group characterizing the exact pattern matching.

In an embodiment, the grouping is based on shifted pattern matching. In an embodiment, such grouping involves determining a pattern matching by shifting the pattern representations with respect to each other and comparing the shifted pattern representations. For example, the grouping process involves shifting a first pattern of the set of patterns with respect to a second pattern of the set of patterns to produce a shifted representation of the first pattern. The shifted representation of the first pattern is compared with the second pattern representation. Based on the comparison results the shifted representation and the second pattern representation, a determination is made whether the first pattern and the second pattern are shifted with respect to each other. Responsive to the patterns being the shifted, the first pattern and the second pattern are grouped in a second group characterizing a shifted pattern matching. In an embodiment, determining whether the first pattern and the second pattern are shifted with respect to each other is based on a first element and/or a last element in the comparison results. In an embodiment, the shifting involves comparing a first component of the shifted representation and a first component of the second pattern representation to determine a type of first non-intersected feature portions in the respective pattern representations; and responsive to the first components being different, moving the first pattern with respect to the second pattern until the first components match.

In an embodiment, the grouping is based on fuzzy pattern matching. In an embodiment, such grouping involves determining a fuzzy pattern matching based on a comparison between the pattern representations of the set of patterns. In an embodiment, the grouping process involves comparing a first pattern representation associated with a first pattern of the set of patterns with a second pattern representation associated with the second pattern of the set of patterns. Based on the comparison, a determination is made whether characteristics of the first pattern and the second pattern within a desired tolerance limit. Responsive to the first pattern representation and the second pattern representation being within the tolerance limit, the first pattern and the second pattern are grouped in a third group characterizing the fuzzy pattern matching.

In an embodiment, grouping the first pattern and the second pattern involves computing a difference representation between the first pattern representation and the second pattern representation; determining whether the first components of the difference representation are same, and values of the second components of the difference representation are within a desired tolerance limit; and responsive to the difference representation being within the desired tolerance limit, grouping the first pattern and the second pattern in the third group characterizing the fuzzy pattern matching.

In an embodiment, the grouping is based on a fuzzy matching for shifted patterns. In an embodiment, such grouping involves shifting one pattern with respect to another pattern of the set of patterns; and determining a fuzzy pattern matching based on a comparison between pattern representations of the shifted pattern and the another pattern. In an embodiment, the grouping involves shifting a first pattern of the set of patterns with respect to a second pattern of the set of patterns to produce a shifted representation of the first pattern. The shifted representation of the first pattern is compared with the second pattern representation. Based on the comparison results of the shifted representation and the second pattern representation, a determination is made whether the first pattern and the second pattern are shifted with respect to each other, and whether the comparison results are within a desired tolerance. Responsive to the comparison results indicating shifted patterns and within the desired tolerance, the first pattern and the second pattern are grouped in a fourth group characterizing a shifted pattern with fuzzy matching.

In an embodiment, one or more patterns of the set of patterns comprises a vertex portion. In an embodiment, grouping the vertex portions involves comparing pattern representations of the one or more non-intersected feature portion candidates with the pattern representations of the set of patterns; and grouping, based on the comparison, the vertex pattern into one or more groups. In an embodiment, the non-intersected feature pattern candidates are determined by defining an adjustable bounding box; and partitioning, using the adjustable bounding box, portions of the vertex pattern into one or more non-intersected feature portions. In an embodiment, a size of the adjustable bounding box is adjusted such that a maximum area having the non-intersected feature portion within the vertex portion is covered.

In an embodiment, the set of patterns comprises parallel non-intersected feature portions, horizontal non-intersected feature portions, vertical non-intersected feature portions, and/or inclined non-intersected feature portions, where a feature portion is inclined with respect to the designated edge. For the horizontal or the vertical non-intersected feature portions, the projected refers to intersection of the non-intersected feature portion with the designated edge. For the inclined non-intersected feature portions, the projected refers to intersection of the inclined non-intersected feature portion with an extended portion of the designated edge.

In an embodiment, the method further involves obtaining the set of patterns further comprising one or more inclined patterns comprising the inclined non-intersected feature portions within a bounding box of an inclined pattern; and encoding each of the inclined patterns to the pattern representation having a first element set and a second element set, wherein the first element set correspond to the designated edge and a second element set correspond to another edge different from the designated edge of the bounding box of the inclined pattern. In an embodiment, the encoding of included feature portions involves projecting the inclined non-intersected feature portions of the inclined pattern along an extended designated edge of the bounding box; and encoding the projected inclined non-intersected feature portions into elements, each element comprising a first component indicating feature portion type and a second component indicating a width.

According to an embodiment, there is provided a computer system comprising a non-transitory computer readable medium having instructions recorded thereon. The instructions, when executed by a computer, implement the method steps above.

### BRIEF DESCRIPTION OF THE DRAWINGS

The above aspects and other aspects and features will become apparent to those ordinarily skilled in the art upon review of the following description of specific embodiments in conjunction with the accompanying figures, wherein:

FIG. 1 shows a block diagram of various subsystems of a lithography system, according to an embodiment;

FIG. 2 illustrates an exemplary portion of a design layout from which several clips at a plurality of locations are selected, according to an embodiment;

FIG. 3A illustrates an exemplary vertex pattern and FIG. 3B illustrates an exemplary zero-vertex pattern, according to an embodiment;

FIG. 4A is an exemplary flow chart of a method for pattern grouping, according to an embodiment;

FIG. 4B is an exemplary flow chart for exact pattern grouping, according to an embodiment;

FIG. 4C is an exemplary flow chart for fuzzy pattern grouping, according to an embodiment;

FIG. 4D is an exemplary flow chart for shifted pattern grouping, according to an embodiment;

FIG. 4E is an exemplary flow chart for grouping patterns having vertex within a bounding box, according to an embodiment;

FIGS. 5A-5D illustrate different feature portions being oriented at different angles with respect to a boundary of respective patterns, according to an embodiment;

FIG. 6A illustrates a comparison between a first pattern and a second pattern that can be grouped into a first group (e.g., an exact pattern match), according to an embodiment;

FIG. 6B illustrates a comparison between a first pattern and a third pattern that may not be grouped into a first group (e.g., an exact pattern match), according to an embodiment;

FIG. 6C illustrates a comparison between a first pattern and a fourth pattern that may not be grouped into a first group (e.g., an exact pattern match), according to an embodiment;

FIG. 7 illustrates pattern matching between inclined patterns that may be grouped into the first group, according to an embodiment;

FIG. 8 illustrates an exemplary fuzzy pattern matching, according to an embodiment;

FIGS. 9A and 9B illustrates an exemplary shifted pattern matching, according to an embodiment;

FIG. 10 illustrates another example of shifted pattern matching, according to an embodiment;

FIG. 11 illustrates shifted pattern matching where the patterns have inclined features, according to an embodiment;

FIGS. 12A and 12B illustrates an exemplary shifted pattern with fuzzy pattern matching, according to an embodiment;

FIG. 13 illustrates another exemplary shifted pattern with fuzzy pattern matching, according to an embodiment;

FIG. 14 illustrates decomposition of a vertex pattern into zero-vertex pattern candidates, according to an embodiment;

FIG. 15 illustrates matching between the vertex pattern using the zero-vertex pattern candidates of FIG. 14 with another zero-vertex pattern, according to an embodiment;

FIG. 16 schematically depicts an embodiment of a scanning electron microscope (SEM), according to an embodiment;

FIG. 17 schematically depicts an embodiment of an electron beam inspection apparatus, according to an embodiment; and

FIG. 18 is a block diagram of an example computer system, according to an embodiment.

### DETAILED DESCRIPTION

The following presents an example environment in which embodiments may be implemented.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” may be used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as “critical dimension” (CD). A critical dimension of a device can be defined as the smallest width of a line or hole or the smallest space between two lines or two holes. Thus, the CD determines the overall size and density of the designed device. Of course, one of the goals in device fabrication is to faithfully reproduce the original design intent on the substrate (via the patterning device).

The pattern layout design may include, as an example, application of resolution enhancement techniques, such as optical proximity corrections (OPC). OPC addresses the fact that the final size and placement of an image of the design layout projected on the substrate will not be identical to, or simply depend only on the size and placement of the design layout on the patterning device. It is noted that the terms “mask”, “reticle”, “patterning device” are utilized interchangeably herein. Also, person skilled in the art will recognize that, the term “mask,” “patterning device” and “design layout” can be used interchangeably, as in the context of RET, a physical patterning device is not necessarily used but a design layout can be used to represent a physical patterning device. For the small feature sizes and high feature densities present on some design layout, the position of a particular edge of a given feature will be influenced to a certain extent by the presence or absence of other adjacent features. These proximity effects arise from minute amounts of radiation coupled from one feature to another or non-geometrical optical effects such as diffraction and interference. Similarly, proximity effects may arise from diffusion and other chemical effects during post-exposure bake (PEB), resist development, and etching that generally follow lithography.

In order to increase the chance that the projected image of the design layout is in accordance with requirements of a given target circuit design, proximity effects may be predicted and compensated for, using sophisticated numerical models, corrections or pre-distortions of the design layout. The article “Full-Chip Lithography Simulation and Design Analysis-How OPC Is Changing IC Design”, C. Spence, Proc. SPIE, Vol. 5751, pp 1-14 (2005) provides an overview of current “model-based” optical proximity correction processes. In a typical high-end design almost every feature of the design layout has some modification in order to achieve high fidelity of the projected image to the target design. These modifications may include shifting or biasing of edge positions or line widths as well as application of “assist” features that are intended to assist projection of other features.

An assist feature may be viewed as a difference between features on a patterning device and features in the design layout. The terms “main feature” and “assist feature” do not imply that a particular feature on a patterning device must be labeled as one or the other.

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include:
a programmable mirror array. An example of such a device is a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means.
a programmable LCD array. An example of such a construction is given in U.S. Pat. No. 5,229,872, which is incorporated herein by reference.

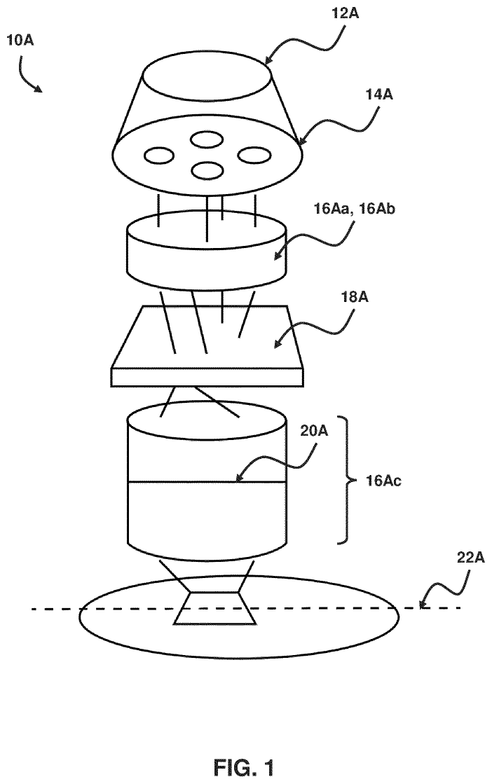

As a brief introduction, FIG. 1 illustrates an exemplary lithographic projection apparatus 10A. Major components are a radiation source 12A, which may be a deep-ultraviolet excimer laser source or other type of source including an extreme ultra violet (EUV) source (as discussed above, the lithographic projection apparatus itself need not have the radiation source), illumination optics which, e.g., define the partial coherence (denoted as sigma) and which may include optics 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(Θₘₐₓ), wherein n is the refractive index of the media between the substrate and the last element of the projection optics, and Θₘₐₓ is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist layer on the substrate is exposed and the aerial image is transferred to the resist layer as a latent “resist image” (RI) therein. The resist image (RI) can be defined as a spatial distribution of solubility of the resist in the resist layer. A resist model can be used to calculate the resist image from the aerial image, an example of which can be found in U.S. Patent Application Publication No. US 2009-0157360, the disclosure of which is hereby incorporated by reference in its entirety. The resist model is related to properties of the resist layer (e.g., effects of chemical processes which occur during exposure, PEB and development). Optical properties of the lithographic projection apparatus (e.g., properties of the source, the patterning device and the projection optics) dictate the aerial image. Since the patterning device used in the lithographic projection apparatus can be changed, it may be desirable to separate the optical properties of the patterning device from the optical properties of the rest of the lithographic projection apparatus including at least the source and the projection optics.

Although specific reference may be made in this text to the use of lithography apparatus in the manufacture of ICs, it should be understood that the lithography apparatus described herein may have other applications, such as the manufacture of integrated optical systems, guidance and detection patterns for magnetic domain memories, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The terms “radiation” and “beam” used herein encompass all types of electromagnetic radiation, including ultraviolet (UV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

In semiconductor manufacturing, pattern selection or pattern matching may be employed to make the semiconductor manufacturing process more efficient. Depending on the application, the pattern selection or the pattern matching can improve computational efficiencies, save measurement time, or improve throughput. For example, a design pattern may include millions of patterns, so performing computational lithography, or model calibration/training related to models of the patterning process can be computationally intensive and may take weeks or months to obtain desired results. In another application, after printing a pattern on a chip, the chip may have hundreds of thousands of patterns that may be desired to be measured in order to control, e.g., control parameters of a patterning apparatus or a process. However, measuring such large number of patterns is impractical in manufacturing setup as it will significantly reduce the throughput of the manufacturing process. As such, a reduced set of patterns is desired.

Various applications, issues, and advantages related to pattern selection and pattern matching are discussed in U.S. Pat. No. 9,934,350 that describes pattern selection for source and mask optimization, and U.S. Pat. No. 8,694,928 that describes pattern selection for lithographic model calibration, both of which are incorporated herein by reference in its entirety.

The present application provides mechanisms for pattern grouping or pattern selection based on feature portions with non-intersected feature edges within a bounding box. For example, the non-intersecting feature edges within a bounding box do not have a vertex or a corner formed by two-intersecting lines or a curve. These feature portions can be commonly found at several locations of a design layout, an image related to a patterned substrate, or an image related to a lithographic process. However, there is a lack of mechanisms that allow good pattern matching or grouping for patterns that do not have a vertex or where the patterns are inclined. Existing methods related to pattern selection, pattern matching or pattern grouping typically use vertex-based query and therefore are not capable of handling zero-vertex patterns (e.g., comprising parallel bars and spaces). Also, a feature inclination makes the vertex-based query more complex.

The existing vertex-based pattern matching apply hashcode to the vertices within a pattern bounding box that defines a portion of pattern. Based on the hashcodes corresponding to two patterns, a system can determine whether two patterns should belong to the same group or not. The traditional hashcode based pattern comparison is limited to an exact matching since there is no directly correlation between a hashcode and pattern geometry. In other words, a one letter difference in hashcode can lead to very different geometric looking of patterns.

Additionally, existing methods are not able to handle certain patterns because the vertex-based methods cannot directly compare vertex patterns to a pattern without a vertex. The vertex-based methods lack a capability to find the certain pattern portions (e.g., having no vertex) within a vertex pattern. Some chip patterns, for example, those used in logic and memory circuits require grouping of two different types of patterns. However, vertex-based pattern grouping cannot always meet pattern matching requirements, for example, matching between vertex pattern and certain pattern that do not include a vertex.

Existing vertex-based methods have computational run time issues associated with certain patterns that do not have exact vertex configuration or hashcodes. For example, using vertex-based method determining grouping or pattern matching between shifted patterns (where one pattern may be shifted with respect to another) may be computationally intensive due amount of shifting and comparisons required in each shifting of patterns. Similar computational issues arise in comparing patterns having a fuzzy pattern with shifted patterns. For each shifted pattern and its comparison with other patterns, a search in a two-dimensional plane is required so there will be multiple positions to compare. Thus, computational run time is high as well as computational expensive. The existing methods do not support to pattern grouping for certain patterns having inclined features (e.g., 45-degree inclined features). The existing methods do not support to comparison between fuzzy patterns, where one or more features of a pattern may have slightly different size compared to a similar different pattern, but such size difference may be within an allowable tolerance.

The mechanisms herein enable pattern grouping based on certain patterns (e.g., with no vertex) and categorize these patterns into one or more pattern groups such as an exact pattern grouping, a shifted pattern grouping, a fuzzy pattern grouping, and a shifted and fuzzy pattern grouping. The mechanisms herein provide several advantages. The mechanism herein allows pattern comparison between a vertex pattern and patterns with no vertex. The mechanism herein can be efficiently applied to various types of patterns including patterns with similar features but at a shifted in position, and/or similar patterns with dimensions within a desired limit. The mechanism herein improves the run time issue associated with shifted patterns. The mechanism herein supports pattern comparisons having inclined features. For example, the mechanisms herein enable comparisons between certain patterns having 45-degree inclined features in a shifted pattern, which was not possible with existing vertex-based methods.

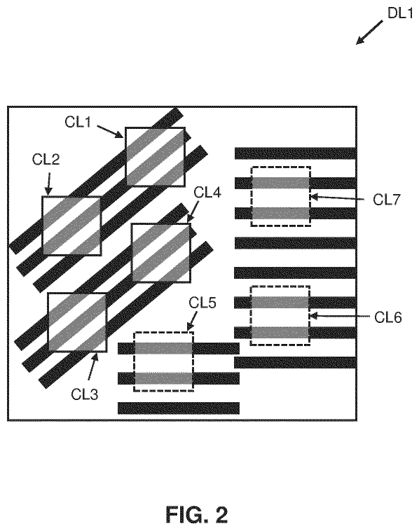

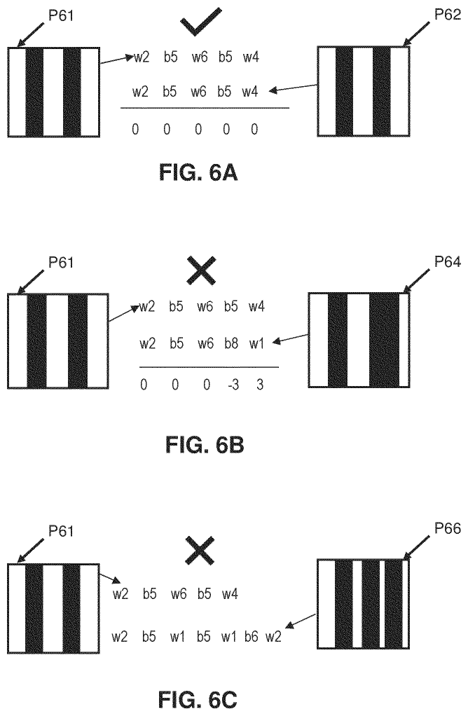

FIG. 2 illustrates an exemplary portion of a design layout from which several clips C1-C7 at a plurality of locations are selected, according to an embodiment. A clip may correspond to a particular location associated with the design layout and includes a pattern portion enclosed by a bounding box. The patterns of the clips may further include entire features or feature portions associated with the design layout. In an embodiment, the clips may correspond to locations or features of interest for process monitoring, metrology or inspection measurement, or modeling, e.g., optical proximity correction, source mask optimization, hot spot prediction, etc. In an embodiment, hundreds or thousands of such clips may be selected from a design layout. The clips may include similar patterns, as such it would be more efficient to group these clips based on the pattern matching. The present disclosure provides mechanisms for grouping similar pattern clips based on matching between feature portions. In an embodiment, the mechanism includes encoding the feature portions into a representation that can compared in a computationally efficient manner. For example, two-dimensional (2D) feature portions may be converted to a representation that are computationally more efficient compared to the 2D representations. Example encoding of the clips and comparison of different encoded representations are discussed in detail with respect to FIGS. 6A-6C, 7, 8, 10, 11, 13, and 15. It can be understood that the present disclosure is not limited to clips from a design layout. In some embodiments, the clips may be provided by a user from a deign layout, an image of a design layout, an aerial image, a mask image, a resist image, an etch image, or other patterning process related simulated images, measured images or other metrology data.

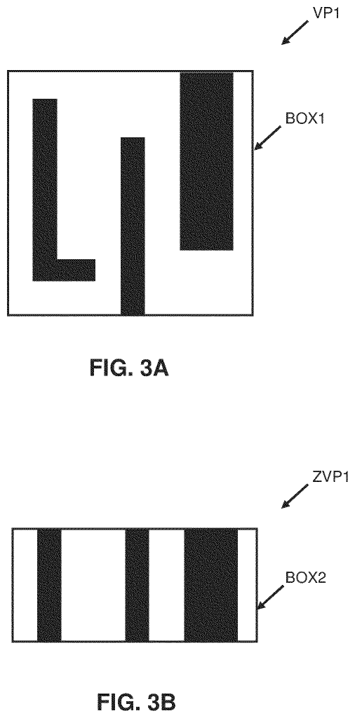

FIG. 3A illustrates an exemplary pattern VP1 within a clip and FIG. 3B illustrates another exemplary pattern ZVP1 within another clip, according to an embodiment. The pattern within the clip VP1 is bounded by a bounding box BOX1. Similarly, the pattern within the clip ZVP1 is bounded by a bounding box BOX2. The pattern VP1 in the clip includes a plurality of polygon shaped features such as an L-shaped feature and two vertical features of different sizes. The features in the clip VP1 include vertices or corners that define a polygon shape of the features. On the other hand, the pattern in the clip ZVP1 includes portions of the features where two feature edges do not intersect within the bounding box of the clip ZVP1. In an embodiment, the features in the clip ZVP1 may be referred as a zero-vertex feature and the pattern portion may be referred as the zero-vertex pattern. The present disclosure enables comparison between clips that similar to ZVP1, or comparison between different types of clips like ZVP1 and VP1.

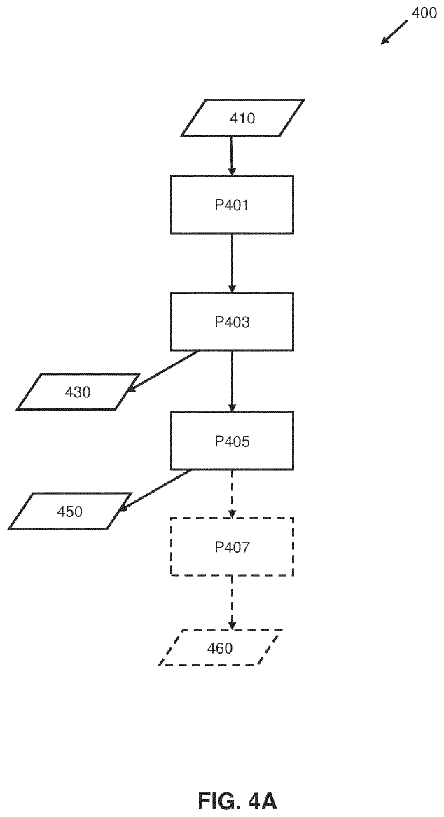

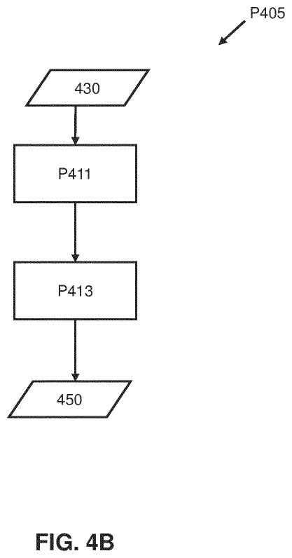

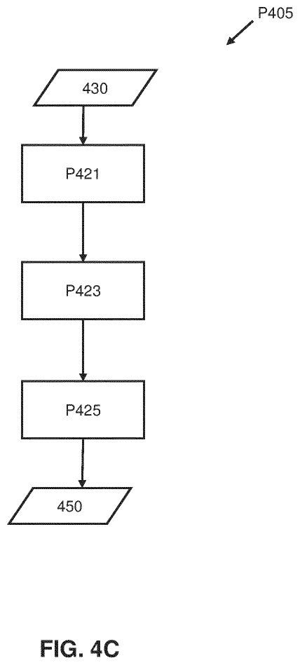

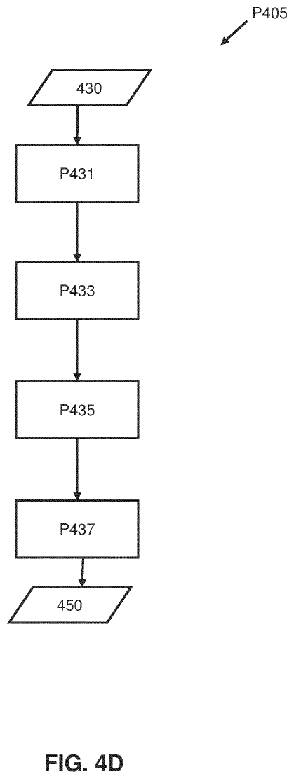

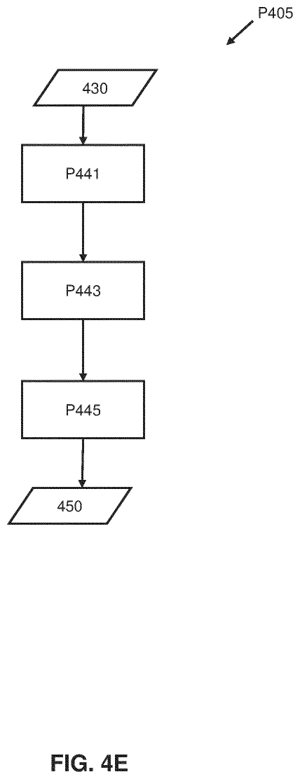

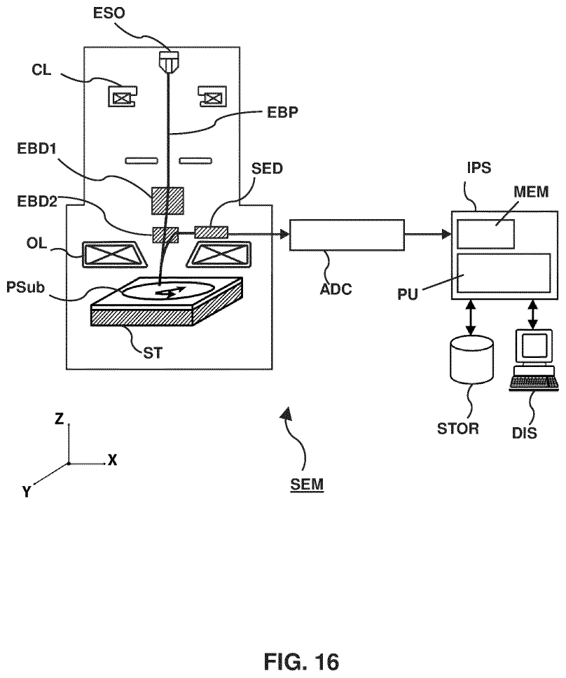

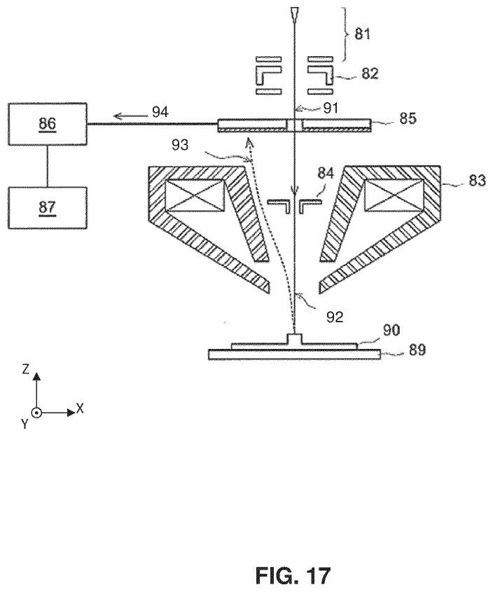

FIG. 4A is a flow chart of an exemplary method 400 for pattern grouping, according to an embodiment. In the method 400, the pattern grouping is based on pattern portions having non-intersected feature portions with no intersected feature edges within a bounding box. The method 400 provides several pattern matching options that enables two or more patterns to be grouped into different groups such as exact matching group, a fuzzy matching group, a shifted pattern group, or a combination thereof. In an embodiment, a user may select one or more grouping techniques to enable exact matching, fuzzy matching, shifted matching or a combination thereof. The method 400 encodes a 2D pattern into a pattern representation, which is further used for comparing and grouping two or more patterns. The encoded pattern representation provides a compact representation of 2D pattern for pattern matching purposes and improves computational runtime and efficiency substantially compared to pattern matching performed using 2D patterns. Based on a pattern grouping result, a representative pattern may be selected from each group and the selected patterns may be provided for different applications related to a patterning process. Thus, a reduced set of patterns are made available that can improve other aspects of a patterning process. For example, the selected patterns may be provided to a metrology tool (e.g., FIGS. 16 and 17) for measurement purposes, for model calibration, or for training a model related to lithographic process. Using the selected patterns instead of an entire set of patterns can improve the measurement time, or model calibration without substantially affecting the accuracy of calibrated models or measurements. Thus, the throughput of a patterning process or the measurement process can be improved significantly. The method 400 is further discussed in detail using example operation or processes P401, P403, and P405.

Process P401 involves obtaining a set of patterns 410 of one or more design layouts. A pattern of the set of patterns 410 comprises a non-intersected feature portion within a bounding box of the pattern. In an embodiment, a first set of patterns may be from the one or more design layouts. For example, a first set of patterns may be selected from a first design layout at a center, and at corners of the first design layout using a first bounding box of size 2 mm×2 mm (or other units). Further, a second set of patterns may be selected from the one or more design layout based on the first set of patterns, where each pattern of the second set of patterns includes an additional area around a corresponding pattern of the first set of patterns. For example, using a center of a first pattern from the first set of patterns, a second bounding box larger than the first bounding box may be used to select a pattern for the second set of patterns. As an example, the second bounding box may be, for example, a 3 mm×3 mm in size, which covers additional feature portions outside the 2 mm×2 mm box. In an embodiment, the set of patterns 410 includes the first set of patterns of the one or more design layouts, the second set of patterns, or a combination thereof.

In an embodiment, a non-intersected feature portion of a pattern may be a portion of a pattern in which feature edges do not intersect each other within the defined boundary. For example, the non-intersected feature portions do not have a vertex or a corner, such as a vertex or a corner of a polygon (e.g., square, rectangle, L-shape, etc.) formed by two intersecting lines. The non-intersected feature portion may include feature portions that are substantially parallel to each other. The non-intersected feature portion may include feature edges having straight edges, curved edges, wavy edge, a bump along a straight edge, or other type of edges without a vertex. In an embodiment, the feature edges of the feature portions extend from one edge of a bounding box to an opposite edge of the bounding box, where the bounding box defines the boundary of a pattern under consideration. In an embodiment, the non-intersected feature portions may include feature portions oriented vertically, horizontally, or inclined with respect to the bounding box. In an embodiment, the non-intersected feature portion may include feature edges that are substantially parallel to each other. In an embodiment, the non-intersected feature portion may include feature edges that are not parallel to each other, but do not intersect each other within the bounding box. The feature edges intersect a boundary of the bounding box. In an embodiment, a non-intersected feature portion may have a uniform width measured between two adjacent feature edges. In an embodiment, a non-intersected feature portion may have a non-uniform width, in which case, a minimum width, a maximum width, an average width, or a combination thereof may be determined and used for a pattern representation.

In an embodiment, each pattern of the set of patterns 410 may be represented as an image associated with a patterning process. In an embodiment, the image corresponds to a design layout image, a mask image, an aerial image, an etch image, or a metrology image. In an embodiment, the image is a binary image, wherein a bar is represented in a first color and a space is presented in a second color. In an embodiment, the individual non-intersected feature portion comprises a bar or a space, and the pattern comprises one or more bars and one or more spaces. In an embodiment, each pattern of the set of patterns 410 is represented as contours associated with a patterning process. In an embodiment, the contours correspond to contours extracted from a design layout, a mask image, an aerial image, an etch image, or a metrology image.

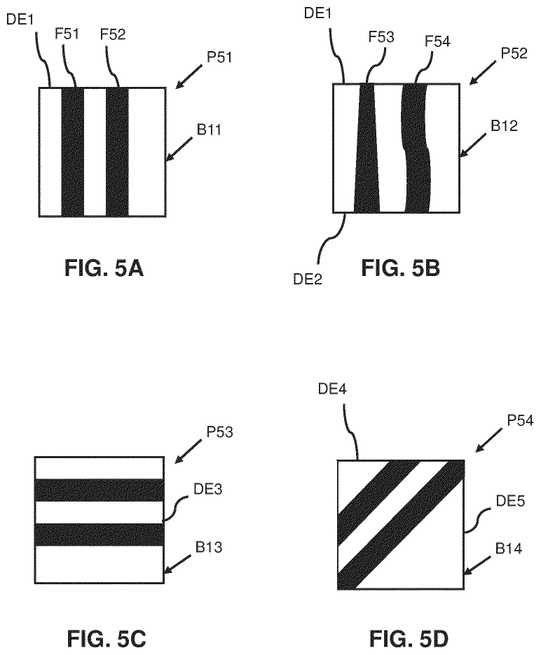

FIGS. 5A-5D illustrate exemplary patterns that may be included in a set of patterns. Each of the patterns includes one or more non-intersected feature portions. The non-intersected feature portions may be oriented at a particular angle with respect to a boundary of respective patterns. For example, in FIG. 5A, a first pattern P51 includes non-intersected feature portions F51 and F52 shown as vertical dark bars separated by spaces. The first pattern P51 does not include any vertex (e.g., corner, or vertex of a polygon shape). In the first pattern P51, the non-intersected features are substantially parallel to each other and have uniform width. The first pattern P51 may be bounded by a bounding box B11. An edge (e.g., DE1) of the bounding box B11 may be assigned as a designated edge along which measurement of different non-intersected features may be determined. In some embodiments, the designated edge (e.g., DE1) may be extended towards a left side or a right side to project edges of non-intersected features, if any.

In an embodiment, in FIG. 5B, a second pattern P52 may be bounded by a bounding box B12 and may include non-intersected feature portions having different geometry compared to the first pattern P51. For example, in the pattern P52, a first non-intersected feature F53 has a different shape than a second non-intersected feature F54. In an embodiment, the non-intersected features F53 and F54 may not have a uniform width. In this example, a width of the features F53 and F54 may be measured along a designated edge DE1, another designated edge DE2, or both.

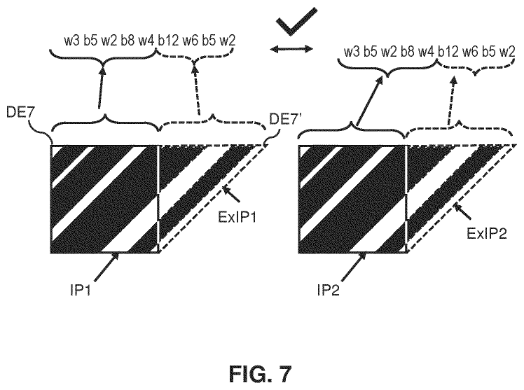

Another example shown in FIG. 5C illustrates a third pattern P53 may be bounded by a bounding box B13 that includes non-intersected feature portions that are oriented horizontally. In this example, each non-intersected feature portion has a uniform width along a length of the feature portion. A width of the non-intersected features portions may be measured along a designated edge DE3. As yet another example, as shown in FIG. 5D, a fourth pattern P54 may be bounded by a bounding box B14 that includes inclined non-intersected feature portions that are oriented horizontally. In this example, each non-intersected feature portion has a uniform width along a length of the feature portion. In this example, width of the non-intersected feature portions may be measured along a designated edge DE4 and along an extended edge of DE4. An example illustration of extended edge of a designated edge is shown in FIG. 7.

Referring back to FIG. 4A, process P403 involves encoding a non-intersected feature portion of a pattern of the set of patterns 410 into a pattern representation 430 that is computationally efficient. The pattern representation 430 enables comparison between patterns having different shapes and sizes. For example, the pattern representation 430 is improves computational runtime compared to using a 2D representation such as an image or polygon shape. In an embodiment, the pattern representation 430 has a set of elements, each element comprising a first component indicating a type of an individual non-intersected feature portion, and a second component indicating a dimension (e.g., width) of an individual non-intersected feature portion projected along a designated edge of an area enclosing the pattern. In an embodiment, the type of an individual non-intersected feature portion may be represented by white color or black color. For example, the type of an individual non-intersected feature portion comprise design layout polygon portions where black corresponds to a portion of a polygon and white may correspond to a space between polygons. As another example, a pattern of 410 may be an image, wherein a type of an individual non-intersected feature portion may be characterized by different ranges of pixel intensities. For example, a first type of feature portion may correspond to a first pixel intensity range (e.g., characterizing black color) and a first type of feature portion may correspond to a second pixel intensity range (e.g., characterizing white color). In an embodiment, the pattern representation 430 may be a vector, and the first component of the vector is a first digit, and the second component of the vector is a second digit.

In an embodiment, the set of patterns 410 may include parallel feature portions where the feature edges do not intersect each other inside a bounding box of a pattern. In an embodiment, the set of patterns 410 may include horizontal non-intersected feature portions where feature edges are oriented horizontally. In an embodiment, the set of patterns 410 may include vertical non-intersected feature portions where the feature edges are oriented vertically. In an embodiment, the set of patterns may include inclined non-intersected feature portions, where feature edges are inclined with respect to the designated edge of a bounding box of a pattern.

In an embodiment, for the horizontal or the vertical non-intersected feature portions, the projected refers to intersection of the non-intersected feature portion with the designated edge of the bounding box. For example, in case of vertically oriented feature portions, feature edges intersect a horizontal edge of the bounding box. In case of a horizontally oriented feature portion, feature edges intersect a vertical edge of the bounding box. FIGS. 6A-6C, 10, 13 and 15 (discussed later in the disclosure) provides examples of encoding for vertically oriented feature portions.

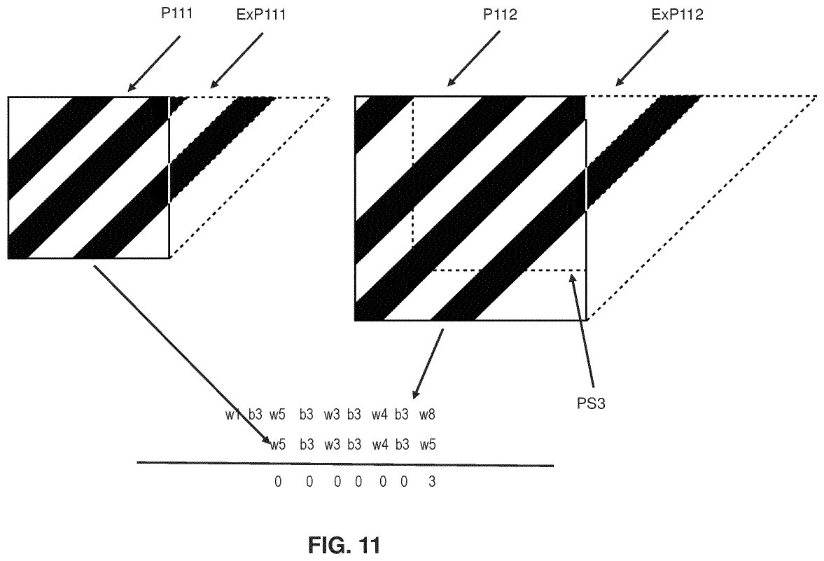

In an embodiment, for the inclined non-intersected feature portions, the projected refers to intersection of the inclined non-intersected feature portion with an extended portion of the designated edge. In an embodiment, an inclined pattern can also be encoded into a pattern representation 430 having a first element set and a second element set, where the first element set correspond to the designated edge and a second element set correspond to another edge different from the designated edge of the bounding box of the inclined pattern. In an embodiment, to determine a second element set, the inclined non-intersected feature portions of the inclined pattern may be projected along the first direction. Based on the projected inclined non-intersected feature portions that interest an extended portion of the designated edge, the second element set may be generated in a similar manner as the first element set. For example, each element of the second set comprises a first component characterizing a feature type along the extended designated edge, and the second component characterizing a width measured along the extended designated edge. FIGS. 7, and 11 (discussed later in the disclosure) provides examples of encoding for inclined patterns.

Referring back to FIG. 4A, process P405 involves grouping the set of patterns 410 into one or more groups by comparing the pattern representations 430 associated the set of patterns 410 to obtain a grouped set of pattern 450. The one or more groups may represent an exact pattern matching, a fuzzy pattern matching, a shifted pattern matching, a combination of shifted and fuzzy pattern matching, or a combination thereof.

In an embodiment, the grouping process P405 involves determining an exact pattern matching based on a comparison between the pattern representations 430 of the set of patterns 410. In an embodiment, exact grouping or exact matching refers to grouping two or more patterns that are exactly identical into a single group. In an embodiment, the identical matching may be determined based on a number of non-intersected feature portions, an angle of features the non-intersected feature portions, a relative position of the non-intersected feature portions with respect to other feature portions within a pattern, or other geometrical characteristics associated with the non-intersected feature portions or the corresponding pattern. In an embodiment, the exact grouping is determined based on a pattern representation of a given 2D pattern. For example, the pattern representation comprises a type of feature and a width of the feature, as discussed herein.

FIG. 4B illustrates example processes of an exact pattern matching. A process P411 involves comparing a first pattern representation (e.g., of 430) associated with a first pattern of the set of patterns 410 with a second pattern representation (e.g., of 430) associated with the second pattern of the set of patterns 410. A process P413 involves responsive to a determination that the first pattern representation and the second pattern representation being the same, grouping the first pattern and the second pattern in a first group characterizing the exact pattern matching. The processes P411 and P413 are repeated until all the patterns of the set of patterns 410 are covered. The exact pattern matching process is further explained using examples in FIGS. 6A-6C.

FIGS. 6A-6C illustrate different patterns can be grouped into a first group characterizing an exact matching, according to some embodiments. FIG. 6A illustrates a comparison between a first pattern P61 and a second pattern P62 that are grouped into a first group (e.g., an exact pattern match). The first pattern P61 and the second pattern P62 each include non-intersected feature portions. According to an embodiment, each of the first pattern P61 and the second pattern P62 may be represented as a string or vector of elements, where each element includes a first component indicating a feature type, and a second component indicating a width of a non-intersected feature portion. For example, the first pattern P61 may be represented as a first vector [w2; b5; w6; b5; w4] or other representation, and the second pattern P62 may be represented as a second vector [w2; b5; w6; b5; w4] or other representation. Comparing the first vector and the second vector indicates that the vectors are exactly identical. Based on the comparison of the vectors, the first pattern P61 and the second pattern P62 are grouped into the first group characterizing an exact matching.

In an embodiment, a difference between the first vector and the second vector may be determined. For example, the difference results in a difference vector having elements [0; 0; 0; 0; 0]. Based on the difference vector, the system can check for values of individual elements to determine an exact match. For example, if each element of the difference vector is zero, an exact match may be determined. In an embodiment, only a few elements of the difference vector may be zero, while others may be non-zero. In this case, the patterns cannot be characterized as an exact match. In an embodiment, based on the difference vector, a partially exact match may be determined. For example, if more than two consecutive elements of the difference vector are zero, then the non-intersected feature portions corresponding to such consecutive elements may potentially be an exact match. In this case, such partial exact matching portion may be extracted from a given pattern and grouped into the first group. However, if an entire pattern is considered, it may be classified into a different group than the first group.

FIG. 6B illustrates a comparison between the first pattern P61 and a third pattern P64 that may not be grouped into the same group, according to an embodiment. The first pattern P61 and the third pattern P63 each include non-intersected feature portions. Similar to representation of the first pattern P61, the third pattern P64 may be represented as a string or vector of elements, where each element includes a first component indicating a feature type, and a second component indicating a width of a non-intersected feature portion. For example, the third pattern P64 may be represented as a third vector [w2; b5; w6; b8; w1] or other representation. Comparing the first vector and the third vector indicates that the vectors are not exactly identical. Based on the comparison of the vectors, the first pattern P61 and the third pattern P64 are not grouped into the first group characterizing an exact matching.

In an embodiment, a difference between the first vector and the third vector may be determined. For example, the difference results in a difference vector having elements [0; 0; 0; −3; 3]. Based on the difference vector, the system can check for values of individual elements to determine an exact match. For example, the difference vector has only a few elements that are zero, while others may be non-zero. In this case, the patterns are not characterized as an exact match or are not placed into the first group.

FIG. 6C illustrates another comparison between the first pattern P61 and a fourth pattern P64 that may not be grouped into the first group, according to an embodiment. The first pattern P61 and the fourth pattern P66 each include non-intersected feature portions. Similar to representation of the first pattern P61, the fourth pattern P66 may be represented as a sting or vector of elements, where each element includes a first component indicating a feature type, and a second component indicating a width of a non-intersected feature portion. For example, the fourth pattern P66 may be represented as a third vector [w2; b5; w1; b5; w1; b6; w2] or other representation. Comparing the first vector and the fourth vector indicates that the vectors are not identical. In this example, the first vector and the fourth vector have different dimensions. The fourth vector has greater number of elements than the first vector, which indicates the fourth vector has a greater number of non-intersected feature portions compared to the first vector. Based on the comparison of the vectors, the first pattern P61 and the fourth pattern P66 are not grouped into the first group characterizing an exact matching.

FIG. 7 illustrates pattern matching between inclined patterns IP1 and IP2 that may be grouped into the first group, according to an embodiment. The inclined pattern may have some non-intersected feature portions that intersect a designated edge, and some other feature portions that do not intersect the designated edge. In this case, the inclined pattern may be converted into a pattern representation by determining characteristics of the non-intersected feature portions along the designated edge and a projected portion of the designated edge. In an embodiment, instead of extending the designated edge, representation may be determined by assigning another designated edge at which the inclined non-intersected feature portions intersect.

As shown in FIG. 7, the inclined patterns IP1 and IP2 include non-intersected feature portions bounded by a box (solid lines). Furthermore, an extended portion ExIP1 of the inclined pattern IP1 and an extended portion ExIP2 of the inclined pattern IP2 are generated to enable matching between or grouping of the inclined patterns IP1 and IP2, according to an embodiment. Based on the extended portions, the inclined patterns IP1 and IP2 may be converted into a pattern representation such as a string or a vector. In this example, a designated edge DE7 of the bounding box may be assigned to the inclined pattern IP1. In an embodiment, the non-intersected feature portions of the inclined pattern IP1 are projected to intersect an extended designated edge DE7′ (dotted) of the bounding box. Similarly, the non-intersected feature portions of the inclined pattern IP2 are projected to intersect an extended designated edge.

Using the portions intersecting the designated edge and the extended designated edge, the inclined pattern IP1 may be represented as a pattern representation. The pattern representation comprises a first set of elements [w3; b5; w2; b8; w4] corresponding to the designated edge DE7 and a second set of elements [b12; w6; b5; w2] corresponding to the extended edge DE7′. The first set of elements and the second set of elements may be combined to generate a first representation such as a first vector [w3; b5; w2; b8; w4; b12; w6; b5; w2] characterizing the inclined pattern IP1. Similarly, a second representation such as a second vector [w3; b5; w2; b8; w4; b12; w6; b5; w2] may be generated to characterize the other inclined pattern IP2. Comparing the first vector and the second vectors of the respective inclined patterns indicate that the inclined patterns IP1 and IP2 are exactly identical. Thus, the inclined patterns IP1 and IP2 are grouped into the first group characterizing the exact matching.

Referring back to FIG. 4A, the grouping process may include determining a fuzzy pattern matching based on a comparison between the pattern representations 430 of the set of patterns 410. In an embodiment, fuzzy grouping or fuzzy matching refers to grouping two or more patterns that are substantially similar (e.g., within specified tolerance limits), but not identical, into a single group. In an embodiment, the fuzzy matching may be determined based on whether a characteristic (e.g., width) of a non-intersected feature portion is within specified tolerance. In an embodiment, further comparison may be made based on a number of non-intersected feature portions, an angle of features the non-intersected feature portions, a relative position of the non-intersected feature portions with respect to other feature portions within a pattern, or other geometrical characteristics associated with the non-intersected feature portions or the corresponding pattern. In an embodiment, the exact grouping is determined based on a pattern representation of a given 2D pattern. For example, the pattern representation comprises a type of feature and a width of the feature, as discussed above. In an embodiment, the relative position of any edges of the non-intersected feature portions are within a specified value of tolerance.

FIG. 4C illustrates example processes of a fuzzy pattern matching. Process P421 involves comparing a first pattern representation (e.g., of 430) associated with a first pattern of the set of patterns 410 with a second pattern representation (e.g., of 430) associated with the second pattern of the set of patterns 410. Process P423 involves determining, based on the comparison, whether characteristics of the first pattern and the second pattern within a desired tolerance limit. Process P425 involves responsive to the first pattern representation and the second pattern representation being within the tolerance limit, grouping the first pattern and the second pattern in a third group characterizing the fuzzy pattern matching.

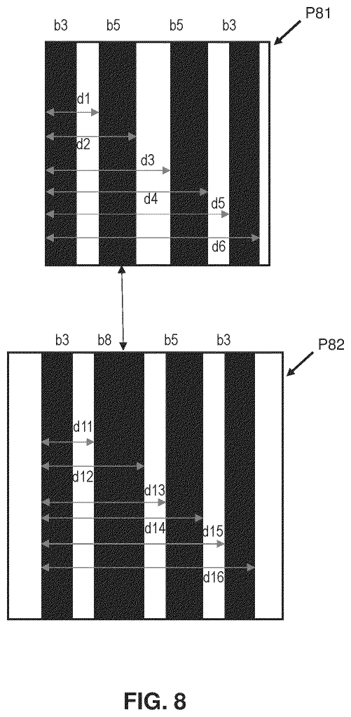

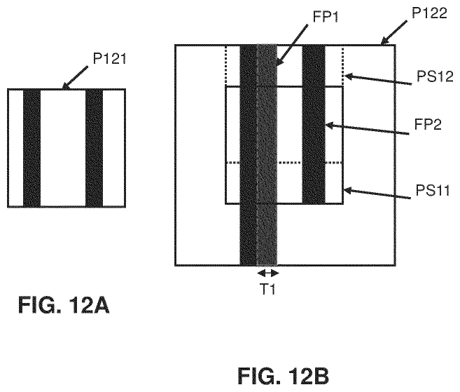

In an embodiment, a difference representation between the first pattern representation and the second pattern representation may be computed. In an embodiment, a determination is made whether the first components of the difference representation have same values and whether the second components have values that are within a desired tolerance limit. Responsive to the difference representation being within the desired tolerance limit, the first pattern and the second pattern may be grouped in the third group characterizing the fuzzy pattern matching. The fuzzy pattern matching is further explained using example in FIGS. 8 and 12.

FIG. 8 illustrates an exemplary fuzzy pattern matching between a pattern P81 and another pattern P82, according to an embodiment. The patterns P81 and P82 each include vertically oriented parallel feature portions of different widths. As discussed with respect to FIGS. 6A-6C, each pattern P81 and P82 may be represented as a pattern representation to determine grouping of the patterns. If no exact matching is found, but there is only a slight different in the pattern, an additional determination of whether the feature portions are within a specified tolerance can be made. For example, after comparing the vectors corresponding to the patterns P81 and P82, it may be determined that the feature types are similar but the widths of the feature portions are not exactly the same. However, such widths may be within a specified tolerance. For example, first feature portions b3 in the patterns P81 and P82 are the same but feature portions b5 and b8 of the patterns P81 and P82, respectively, although of same type are not of same width. However, the difference in widths of b5 and b8 is 3 nm (or other units) which may be within a specified tolerance limit e.g., 5 nm.

In an embodiment, during fuzzy matching a distance between edges of the feature portions may be compared. In an embodiment, a pattern representation incorporating distance between a first edge and each subsequent edge may be determined. In an embodiment, the distances may be computed by adding width of each subsequent feature. For example, for the pattern P81, distance d1-d6 may be determined, and for the pattern P82, distances d11-d16 may be determined. In an embodiment, the pattern representation may be configured to include such distances between feature portions. In an embodiment, the distance may be computed using the width information of the pattern representation. The distances d1-d6 and distances d11-16 may be compared with each other to determine a fuzzy pattern matching. For example, d1 may be compared with d11, d2 may be compared with d12, d3 may be compared with d13, and so on. If the comparison indicates the difference in distances are within a specified tolerance, a fuzzy matching may be achieved and the patterns e.g., P81 and P82 may be placed in a second group characterizing a fuzzy matching group.

Referring back to FIG. 4A, the grouping process P405 may comprise determining a pattern matching by shifting the pattern representations 430 with respect to each other and comparing the shifted pattern representations. In an embodiment, shifting pattern matching enables a location of a pattern that is compared against another pattern to be shifted within a maximum allowable range. Such shifting pattern matching may be used when a clip size (e.g., bounding box area) of one of the patterns being compared is larger than the other.

FIG. 4C illustrates exemplary processes of shifted pattern grouping. Process P431 involves shifting a first pattern of the set of patterns 410 with respect to a second pattern of the set of patterns 410 to produce a shifted representation of the first pattern. In an embodiment, the shifting involves comparing a first component of the shifted representation and a first component of the second pattern representation (e.g., of 430) to determine a type of first non-intersected feature portions in the respective pattern representations; and responsive to the first components being different, moving the first pattern with respect to the second pattern until the first components match.

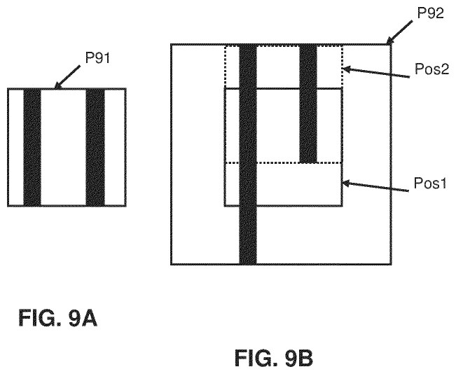

Process P433 involves comparing the shifted representation of the first pattern with the second pattern representation (e.g., of 430). Process P435 involves determining, based on the comparison results the shifted representation and the second pattern representation, whether the first pattern and the second pattern are shifted with respect to each other. In an embodiment, determining whether the first pattern and the second pattern are shifted with respect to each other may be based on a first element and/or a last element in the comparison results. Process P437 involves responsive to the patterns being the shifted, grouping the first pattern and the second pattern in a second group characterizing a shifted pattern matching. The shifted pattern matching is further explained using example in FIGS. 9A-9B, 10, and 11.

FIGS. 9A and 9B illustrates an exemplary shifting pattern matching, according to an embodiment. In an embodiment, patterns of different sizes such as a first pattern P91 smaller than the second pattern P92 may be compared and based on the comparison results it can be determined whether these patterns should be grouped together. In an embodiment, the first pattern 91 may be moved with respect to the second pattern P92 to determine if any portions of the pattern P92 are similar or exact match with the first pattern P91. In an embodiment, as discussed herein, the first pattern P91 and the second pattern P92 may be represented as pattern representations, respectively, such that each element of the representation comprises a first component indicative of a type of a feature portion, and a second component indicative of a width of the feature portion. In an embodiment, the pattern representations may be moved with respect to each other to determine a shifting pattern matching.

As illustrated in FIG. 9B, the first pattern P91 is moved in the bounding box of the second pattern P82 by a specified shift tolerance. For example, a bounding box of the first pattern P91 may be placed at a first position Pos1 (e.g., at a center) of the second pattern P92 and a comparison between the pattern portion at Pos1 and the first pattern P91 can be made. If a match is determined, the second pattern P92 is grouped together with the first pattern P91. If no match is found, the bounding box may be moved to position Pos2 and a similar comparison can be made to determine whether the corresponding pattern portions match. In the present illustration, there could be many possible positions to compare since it is comparison in 2D representation, so the run time is high.

According to the present disclosure, a similar shifting pattern matching is performed using the pattern representation that improves the computational runtime significantly. As an example, the pattern representation may be a vector or a string as discussed earlier. The shifting pattern matching may be performed using following operations, according to an embodiment. At a first operation, a determination is made whether a second length of a second pattern representation of a second pattern (e.g., P92) is greater or equal to a first length of the first pattern representation of the first pattern (e.g., P91). In an embodiment, a length of the pattern representation may be determined based on the number of elements in a pattern representation, or a sum of widths (e.g., sum of second components) of the feature portions.

At a second operation, if the second length is greater, a leading feature portion type is determined. For example, a comparison between first components of the second pattern and the first pattern representation may determine feature portion type. In an embodiment, the leading feature portion of the first pattern may be a first element, while the leading feature portion of the second pattern may be a first element, a second element, a third element or other elements depending on a shift position. For example, when the first pattern P91 is moved with respect to the second pattern P92, a first position may be aligning the first element of the representation of the first pattern P91 with the first element of the representation. After shifting, the first element corresponding to the first pattern P91 may be compared with the second element corresponding to the second pattern P92. If the leading feature portion type is different, keep moving the first pattern representation to right until the leading feature portion type is matching. For example, the leading feature portion type corresponding to the first pattern P91 may be “w” and the leading feature portion type corresponding to the second pattern P92 at a first position may be “w.” Thus, a match between leading feature portion type is found.

The second operation significantly improves the computational runtime, since no computation resources are used for comparison if the check is not satisfied. The comparison for determining a pattern match or grouping is performed only when the leading feature types match thereby saving computational time related to one or more moves of the first pattern with respect to the second pattern.

At a third operation, a comparison between the first pattern representation and the second pattern representation at a current position is determined. Based on the comparison, a determination of an entire pattern matching or partial pattern matching is performed, similar to that discussed earlier with respect to FIG. 6A. If the comparison results indicate a match, the first pattern and the second pattern may be grouped together into a third group characterizing a shifted pattern matching.

In an embodiment, the comparison comprises computing a difference between the first and second pattern representation. If the elements of the difference includes zeros then a match may be found. In an embodiment, all the elements may be zero except the first element and the last element, then a match is determined. Otherwise, the first pattern may be shifted by moving the first representation by one element with respect to the second representation, and the second operation is repeated to continue to determine a match.

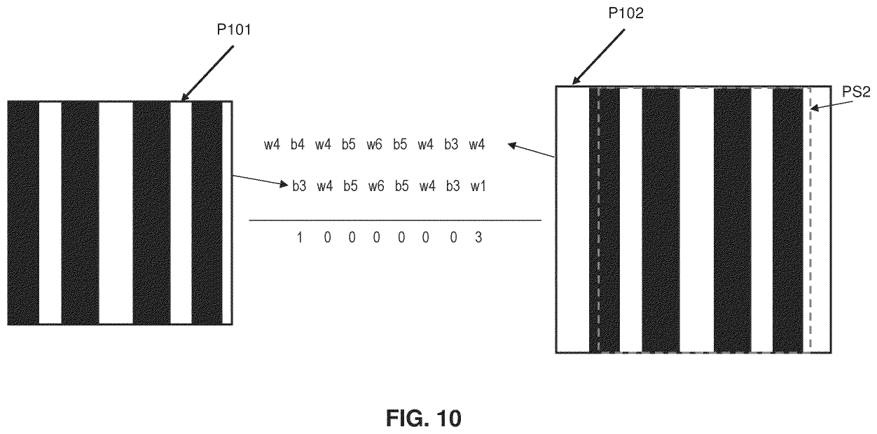

FIG. 10 illustrates an example of shifted pattern matching based on pattern representations, according to an embodiment. In this example, a first pattern P101 is compared with a second pattern P102 using shifted pattern matching. In an embodiment, the first pattern P101 may be represented as a first vector [b3; w4; b5; w6; b5; w4; b3; w1] and the second pattern P102 may be represented as a second vector [w4; b4; w4; b5; w6; b5; w4; b3; w4]. According to the second operation discussed with respect to FIG. 9B, at a first position, the first elements of the first vector and the second vector may be compared, which indicates no matching. For example, the first element of the first vector indicates a feature type “b,” while the first element of the second vector indicates a feature type “w.”

Since, no match is determined at a first position, the first vector may be moved with respect to the second vector into a second position (illustrated by dotted box PS2 in FIG. 10). At the second position, the first element of the first vector is compared with the second element of the second vector, as shown in FIG. 10. At the second position, a match between the feature type is determined. Thus, the third operation (discussed with respect to FIG. 9B) is performed to determine whether the first and second pattern match. As shown in FIG. 10, comparing a portion of the second vector with the first vector indicates a partial match. For example, a difference vector [1; 0; 0; 0; 0; 0; 0; 3] can be computed using a portion of the second vector and the first vector at the second position. Thus, the first and the second patterns P101 and P102 can be grouped into the third group characterizing a shifted pattern matching.

FIG. 11 illustrates shifted pattern matching where the patterns have inclined features, according to an embodiment. The grouping process is similar to that discussed above, however for determining representations of the inclined patterns having inclined feature portions, projected portions are determined. Based on the bounding box and the project portions the representation can be constructed, for example, as discussed with respect to FIG. 7. Using the representation of the inclined patterns, the shifting pattern matching may be performed.

In the example shown, a first pattern P111 is compared with a larger second pattern P112. Inclined feature portions of the first pattern P111 are projected on to an extended edge ExP111 to determine the first pattern representation of the first pattern P111. For example, the first pattern representation may be a first vector [w5; b3; w3; b3; w4; b3; w5]. Similarly, the inclined feature portions of the second pattern P112 are projected on to an extended edge ExP112 to determine the second pattern representation. For example, the second pattern representation may be a second vector [w1; b3; w5; b3; w3; b3; w4; b3; w8].

To determine the grouping of the first pattern P111 and the second pattern P112, the first pattern P111 may be shifted with respect to the second pattern P112 by comparing the first vector to different portions of the second vector. In the example shown, at a third position PS3, the first vector and a portion of the second vector match. For example, at the third position PS3, a difference vector between the first vector and the portion of the second vector is [0; 0; 0; 0; 0; 0; 3]. The difference vector includes zeros except at the last element. Thus, the difference vector indicates that a partial match of the first pattern P111 with the pattern portion at position PS3 of the second pattern P112. Based on this, the first pattern P111 and the second pattern P112 can be grouped into the third group characterizing a shifted pattern matching.

Referring back to FIG. 4A, the grouping process P405 may comprise the grouping based on shifted pattern and fuzzy matching processes discussed above. For example, one pattern may be shifted with respect to another pattern of the set of patterns 410; and a fuzzy pattern matching may be determined based on a comparison between pattern representations of the shifted pattern and the another pattern of the set of pattern 410.

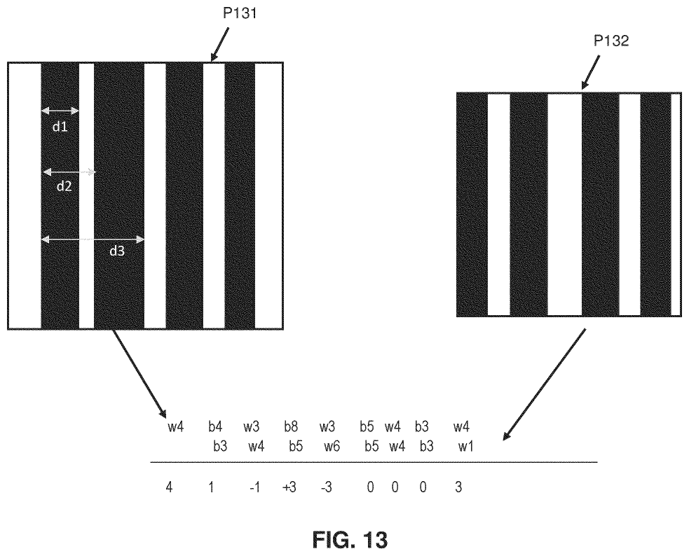

In an embodiment, a first pattern of the set of patterns 410 may be shifted with respect to a second pattern of the set of patterns 410 to produce a shifted representation of the first pattern. The shifted representation of the first pattern may be compared with the second pattern representation (e.g., of 430). Based on the comparison results of the shifted representation and the second pattern representation, a determination is made whether the first pattern and the second pattern are shifted with respect to each other, and whether the comparison results are within a desired tolerance. Responsive to the comparison results indicating shifted patterns and within the desired tolerance, the first pattern and the second pattern may be grouped in a fourth group characterizing a shifted pattern with fuzzy matching. The shifted and fuzzy matching is further explained with respect to FIGS. 12A-12B and 13.

FIGS. 12A and 12B illustrates an exemplary shifted pattern with fuzzy matching, according to an embodiment. Such matching comprises a combination of shifting a pattern with respect to another pattern and determining whether difference between feature portions of the two patterns is within a specified tolerance. If such a combination matching is satisfied, the patterns may be grouped into a fourth group characterizing shifted pattern with fuzzy matching.

FIGS. 12A and 12B illustrates exemplary matching between a first pattern P121 and a second pattern P122. When the first pattern P121 is positioned at a first position PS11 or a second position PS12, a feature portion FP1 of the second pattern P122 is larger than a corresponding feature portion of the first pattern P121, however, the feature portion FP1 is within a tolerance limit T1. As such the first pattern P121 and the second pattern P122 can be grouped into a fourth group characterizing shifted pattern with fuzzy matching. The FIGS. 12A and 12B are only visual representation to explain the concept. Performing such comparison using the shown 2D representations can be computationally intensive. However, using representation of the present disclosure such comparison make the computations faster and more efficient.

FIG. 13 illustrates exemplary shifted pattern with fuzzy matching using representations herein, according to an embodiment. A first pattern P131 is compared with a second pattern P132 using corresponding pattern representations. As shown, the first pattern P131 may be represented as a first vector [w4; b4; w3; b8; w3; b5; w4; b3; w4] and the second pattern P132 may be represented as a second vector [b3; w3; b8; w3; b5; w4; b3; w4]. In this example, the second vector of the second pattern P132 may be shifted with respect to portions of the first vector of the first pattern P131. At each shifted position, the elements of the vectors may be compared to determine whether the vectors satisfy matching conditions. For example, the matching conditions can be related to distances between the feature portions, tolerance limits associated with each feature portions, or both.

In an embodiment, the comparison may be performed by computing a difference vector using the second vector and portions of the second vector. For example, the difference vector is determined as [4; 1; −1; 3; −3; 0; 0; 0; 3]. Each element of the difference vector may be compared with a tolerance limit associated with the corresponding feature portion. If the values of the elements are within the tolerance limits, then a fuzzy match may be determined. Furthermore, in an embodiment, distance difference between all pair edges of the feature portions may be determined. The distance differences may be compared with a shift tolerance to ensure different feature portion types are sufficiently distanced from each other. Example distance difference computation between a first edge of a first feature portion and subsequent edges of subsequent feature portions is illustrated in FIG. 13. For example, a first distance difference d1 may be 1, a second distance difference d2 may be 1+(−1) which equals to 0, a third distance difference d3 may be 1+(−1)+3, which equals to 3. In an embodiment, such distance difference may be computed using the difference vector elements. Thus, in an embodiment, the matching conditions can be tolerances associated with each feature portions, as well as another tolerance limits difference in distances. When both the feature portion related tolerance limits and difference tolerance limits are satisfied the patterns (e.g., P131 and P132) may be grouped into the fourth group.

As mentioned herein, the method 400 herein enables determination of patter matching by comparison between vertex pattern and non-intersecting feature portions. FIG. 4E illustrates exemplary processes for comparing and grouping non-vertex portion and a non-intersecting feature portion, according to an embodiment. In an embodiment, the set of patterns 410 may comprise a non-vertex portion. In an embodiment, process P441 involves determining one or more non-intersected feature portion candidates within the non-vertex portion and such candidates may be used for determining a grouping. In an embodiment, determining the non-intersected feature pattern candidates involves defining an adjustable bounding box; and partitioning, using the adjustable bounding box, portions of the non-vertex pattern into one or more non-intersected feature portions. In an embodiment, a size of the adjustable bounding box may be adjusted such that a maximum area having the non-intersected feature portion within the vertex portion is covered. For each candidate, a pattern representation may be determined as discussed herein.

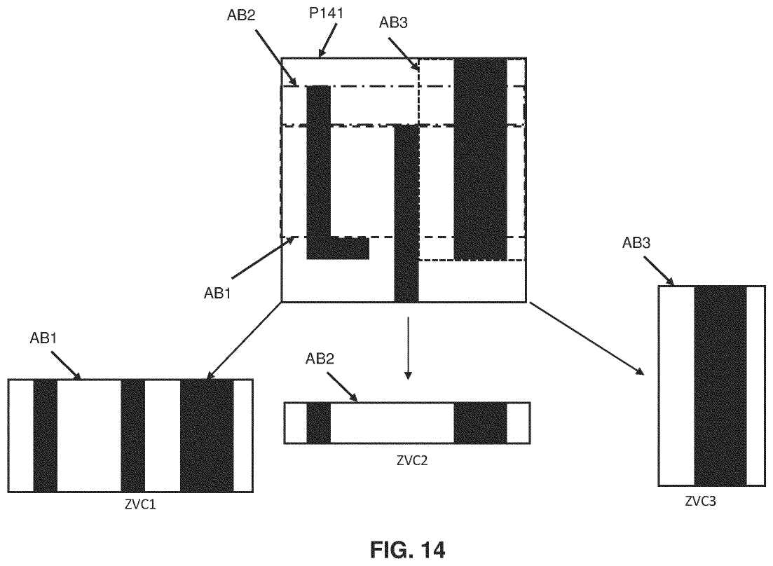

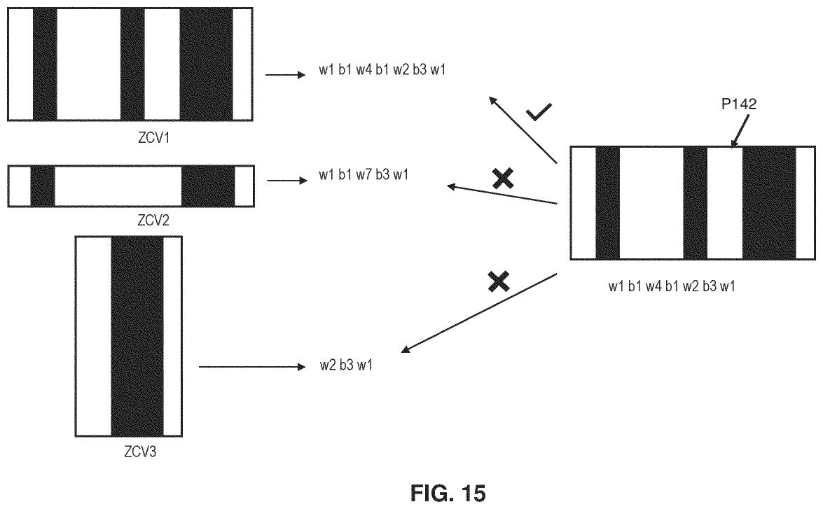

Process P443 involves comparing pattern representations of the one or more non-intersected feature portion candidates with the pattern representations 430 of the non-intersected feature portions within the set of patterns 410. Process P445 involves grouping, based on the comparison results, the non-vertex pattern into one or more groups. In an embodiment, if at least one candidate of the vertex pattern matches a non-intersected feature portion, the vertex pattern may be grouped with the matching non-intersected feature portion. In an embodiment, the vertex pattern may be grouped into a fifth group characterizing matching between a vertex pattern and a non-intersected feature portion. In an embodiment, any of the matching process may be used and the vertex pattern may be grouped into the second group, the third group, or the fourth group, as discussed herein. The grouping of vertex pattern is further discussed in detail with respect to FIGS. 14 and 15 below.

FIG. 14 illustrates decomposition of a vertex pattern into zero-vertex pattern candidates, according to an embodiment. In an embodiment, decomposition is achieved by one or more adjustable boxes configured to crop feature portions of the vertex pattern at different locations. In an embodiment, one location may include multiple adjustable boxes. Each crop comprises feature portions with no vertex. The adjustable box may not be extended beyond the boundary of the vertex pattern. For example, a vertex pattern P141 includes vertices corresponding to the L-shaped feature and the vertical features. The vertex pattern is decomposed by adjustable boxes AB1, AB2, and AB3 such that each box includes feature portions candidates with no vertex. As shown, the adjustable boxes AB1, AB2, and AB3 identifies the feature portion candidates ZVC1, ZVC2, and ZVC3, respectively. Each of the feature portion candidates includes non-intersected feature portions of the vertex pattern but do not include a vertex.

In an embodiment, a valid adjustable box size is determined such that minimum dimension (e.g., a width and a length) of the box is greater than or equal to a minimum dimension (e.g., width) of the ZV pattern box. In an embodiment, a size of the adjustable box is extended to maximum possible area that can be covered such that the feature portions in the adjustable box does not include a vertex.

After the vertex pattern P141 is decomposed into the zero-vertex pattern candidates ZVC1, ZVC2, and ZVC3, a comparison between the candidates ZVC1-ZVC3 and another pattern P142 (in FIG. 15). As shown in FIG. 15, the candidates ZVC1-ZVC3 are compared with the pattern P142 using vector representations in a similar manner as discussed above and the vertex pattern P141 and the pattern P142 may be placed in one or more groups (e.g., the first group, the second group, the third group, or the fourth group). In an embodiment, a matching condition may be satisfied by one candidate, two candidates, or all the candidates.

As shown in FIG. 15, the first candidate ZVC1 may be represented as a first vector [w1; b1; w4; b1; w2; b3; w1], the second candidate ZVC2 may be represented as a second vector [w1; b1; w7; b3; w1], and the third candidate ZVC3 may be represented as a third vector [w2; b3; w1]. Similarly, the pattern P142 may be represented by a fourth vector [w1; b1; w4; b1; w2; b3; w1]. The comparison between the vectors may indicate an exact matching, a fuzzy matching, a shifted matching, or a shifted pattern with fuzzy matching. In the present example, comparing the first vector and the fourth vector indicates an exact pattern matching. While, the second vector and the fourth vector does not match. Similarly, the third vector and the fourth vector does not match. As at least one feature portion candidate (e.g., ZVC1) satisfy the matching condition with the zero-vertex pattern P142, the vertex pattern 141 and the zero-vertex pattern 142 may be considered a match and grouped into a first group characterizing an exact pattern matching.

In an embodiment, the method 400 (in FIG. 4A) may further include a process P407 that involves selecting a representative pattern from each group of the one or more groups to obtain a set of representative patterns 460 for metrology measurements, or training models related to lithographic process. In an embodiment, the representative pattern may be a pattern comprising vertex or no vertex. For example, the representative pattern may include features with intersected feature edges or features with no intersected feature edges. In an embodiment, the representative pattern may be a pattern selected by determining a set of common features of a respective group, and further comprising one or more additional features.

In some embodiments, the inspection apparatus or the metrology apparatus may be a scanning electron microscope (SEM) that yields an image of a structure (e.g., some or all the structure of a device) exposed or transferred on the substrate. FIG. 16 depicts an embodiment of a SEM tool. A primary electron beam EBP emitted from an electron source ESO is converged by condenser lens CL and then passes through a beam deflector EBD1, an E×B deflector EBD2, and an objective lens OL to irradiate a substrate PSub on a substrate table ST at a focus.

When the substrate PSub is irradiated with electron beam EBP, secondary electrons are generated from the substrate PSub. The secondary electrons are deflected by the E×B deflector EBD2 and detected by a secondary electron detector SED. A two-dimensional electron beam image can be obtained by detecting the electrons generated from the sample in synchronization with, e.g., two dimensional scanning of the electron beam by beam deflector EBD1 or with repetitive scanning of electron beam EBP by beam deflector EBD1 in an X or Y direction, together with continuous movement of the substrate PSub by the substrate table ST in the other of the X or Y direction.

A signal detected by secondary electron detector SED is converted to a digital signal by an analog/digital (A/D) converter ADC, and the digital signal is sent to an image processing system IPU. In an embodiment, the image processing system IPU may have memory MEM to store all or part of digital images for processing by a processing unit PU. The processing unit PU (e.g., specially designed hardware or a combination of hardware and software) is configured to convert or process the digital images into datasets representative of the digital images. Further, image processing system IPU may have a storage medium STOR configured to store the digital images and corresponding datasets in a reference database. A display device DIS may be connected with the image processing system IPU, so that an operator can conduct necessary operation of the equipment with the help of a graphical user interface.

As noted above, SEM images may be processed to extract contours that describe the edges of objects, representing device structures, in the image. These contours are then quantified via metrics, such as CD. Thus, typically, the images of device structures are compared and quantified via simplistic metrics, such as an edge-to-edge distance (CD) or simple pixel differences between images. Typical contour models that detect the edges of the objects in an image in order to measure CD use image gradients. Indeed, those models rely on strong image gradients. But, in practice, the image typically is noisy and has discontinuous boundaries. Techniques, such as non-intersecting, adaptive thresholding, edge-detection, erosion, and dilation, may be used to process the results of the image gradient contour models to address noisy and discontinuous images, but will ultimately result in a low-resolution quantification of a high-resolution image. Thus, in most instances, mathematical manipulation of images of device structures to reduce noise and automate edge detection results in loss of resolution of the image, thereby resulting in loss of information. Consequently, the result is a low-resolution quantification that amounts to a simplistic representation of a complicated, high-resolution structure.

So, it is desirable to have a mathematical representation of the structures (e.g., circuit features, alignment mark or metrology target portions (e.g., grating features), etc.) produced or expected to be produced using a patterning process, whether, e.g., the structures are in a latent resist image, in a developed resist image or transferred to a layer on the substrate, e.g., by etching, that can preserve the resolution and yet describe the general shape of the structures. In the context of lithography or other pattering processes, the structure may be a device or a portion thereof that is being manufactured and the images may be SEM images of the structure. In some instances, the structure may be a feature of semiconductor device, e.g., integrated circuit. In this case, the structure may be referred as a pattern or a desired pattern that comprises a plurality of feature of the semiconductor device. In some instances, the structure may be an alignment mark, or a portion thereof (e.g., a grating of the alignment mark), that is used in an alignment measurement process to determine alignment of an object (e.g., a substrate) with another object (e.g., a patterning device) or a metrology target, or a portion thereof (e.g., a grating of the metrology target), that is used to measure a parameter (e.g., overlay, focus, dose, etc.) of the patterning process. In an embodiment, the metrology target is a diffractive grating used to measure, e.g., overlay.

FIG. 17 schematically illustrates a further embodiment of an inspection apparatus. The system is used to inspect a sample 90 (such as a substrate) on a sample stage 88 and comprises a charged particle beam generator 81, a condenser lens module 82, a probe forming objective lens module 83, a charged particle beam deflection module 84, a secondary charged particle detector module 85, and an image forming module 86.

The charged particle beam generator 81 generates a primary charged particle beam 91. The condenser lens module 82 condenses the generated primary charged particle beam 91. The probe forming objective lens module 83 focuses the condensed primary charged particle beam into a charged particle beam probe 92. The charged particle beam deflection module 84 scans the formed charged particle beam probe 92 across the surface of an area of interest on the sample 90 secured on the sample stage 88. In an embodiment, the charged particle beam generator 81, the condenser lens module 82 and the probe forming objective lens module 83, or their equivalent designs, alternatives or any combination thereof, together form a charged particle beam probe generator which generates the scanning charged particle beam probe 92.

The secondary charged particle detector module 85 detects secondary charged particles 93 emitted from the sample surface (maybe also along with other reflected or scattered charged particles from the sample surface) upon being bombarded by the charged particle beam probe 92 to generate a secondary charged particle detection signal 94. The image forming module 86 (e.g., a computing device) is coupled with the secondary charged particle detector module 85 to receive the secondary charged particle detection signal 94 from the secondary charged particle detector module 85 and accordingly forming at least one scanned image. In an embodiment, the secondary charged particle detector module 85 and image forming module 86, or their equivalent designs, alternatives or any combination thereof, together form an image forming apparatus which forms a scanned image from detected secondary charged particles emitted from sample 90 being bombarded by the charged particle beam probe 92.

In an embodiment, a monitoring module 87 is coupled to the image forming module 86 of the image forming apparatus to monitor, control, etc. the patterning process and/or derive a parameter for patterning process design, control, monitoring, etc. using the scanned image of the sample 90 received from image forming module 86. So, in an embodiment, the monitoring module 87 is configured or programmed to cause execution of a method described herein. In an embodiment, the monitoring module 87 comprises a computing device. In an embodiment, the monitoring module 87 comprises a computer program to provide functionality herein and encoded on a computer readable medium forming, or disposed within, the monitoring module 87.

In an embodiment, like the electron beam inspection tool of FIG. 16 that uses a probe to inspect a substrate, the electron current in the system of FIG. 17 is significantly larger compared to, e.g., a CD SEM such as depicted in FIG. 16, such that the probe spot is large enough so that the inspection speed can be fast. However, the resolution may not be as high as compared to a CD SEM because of the large probe spot. In an embodiment, the above discussed inspection apparatus may be single beam or a multi-beam apparatus without limiting the scope of the present disclosure.

The SEM images, from, e.g., the system of FIG. 16 and/or FIG. 17, may be processed to extract contours that describe the edges of objects, representing device structures, in the image. These contours are then typically quantified via metrics, such as CD, at user-defined cut-lines. Thus, typically, the images of device structures are compared and quantified via metrics, such as an edge-to-edge distance (CD) measured on extracted contours or simple pixel differences between images.

In an embodiment, the one or more processes of the method 400 can be implemented as instructions (e.g., program code) in a processor of a computer system (e.g., process PRO of computer system CS). In an embodiment, the procedures may be distributed across a plurality of processors (e.g., parallel computation) to improve computing efficiency. In an embodiment, the computer program product comprising a non-transitory computer readable medium has instructions recorded thereon, the instructions when executed by a computer hardware system implementing the method described herein.

According to present disclosure, the combination and sub-combinations of disclosed elements constitute separate embodiments. For example, a first combination includes encoding of a set of patterns into a computationally efficient representation and determining a grouping based on the encoded pattern representation. The sub-combination may include determining an exact pattern matching. Another sub-combination may include determining a shifted pattern matching. Another sub-combination may include determining a fuzzy pattern matching. In another combination, determining a matching between vertex patterns and non-intersected feature portions. The sub-combination may include determining a grouping based on the matching. A third combination includes determining representative patterns based on grouped patterns and providing the representative patterns for metrology measurements or model calibration.

Embodiments of the present disclosure can be further described by the following clauses.

1. A non-transitory computer-readable medium having instructions recorded thereon, the instructions when executed by a computer implementing a method for grouping patterns associated with one or more design layouts of a semiconductor, the method comprising:
obtaining a set of patterns of one or more design layouts, a pattern of the set of patterns comprising a non-intersected feature portion within a bounding box of the pattern;
encoding a non-intersected feature portion of a pattern of the set of patterns to a pattern representation having elements, each element comprising a first component indicating a type of an individual non-intersected feature portion, and a second component indicating a width of the individual non-intersected feature portion projected along a designated edge of an area enclosing the pattern; and
grouping the set of patterns into one or more groups by comparing the pattern representations associated the set of patterns.
   2. The medium of clause 1, further comprising:
selecting a representative pattern from each group of the one or more groups for metrology measurements, or training models related to lithographic process.
   3. The medium of clause 1, wherein obtaining the set of patterns comprises:
obtaining a first set of patterns of the one or more design layouts; and
selecting, from the one or more design layouts, a second set of patterns based on the first set of patterns, each pattern of the second set of patterns including an additional area around a corresponding pattern of the first set of patterns.
   4. The medium of clause 3, wherein the set of patterns comprises: the first set of patterns of the one or more design layouts, the second set of patterns, or a combination thereof.
   5. The medium of clause 1, wherein the grouping comprises: determining an exact pattern matching based on a comparison between the pattern representations of the set of patterns.
   6. The medium of clause 5, wherein grouping comprises:
comparing a first pattern representation associated with a first pattern of the set of patterns with a second pattern representation associated with the second pattern of the set of patterns; and
responsive to a determination that the first pattern representation and the second pattern representation being the same, grouping the first pattern and the second pattern in a first group characterizing the exact pattern matching.
   7. The medium of clause 1, wherein the grouping comprises: determining a pattern matching by shifting the pattern representations with respect to each other and comparing the shifted pattern representations.
   8. The medium of clause 7, wherein grouping comprises:
shifting a first pattern of the set of patterns with respect to a second pattern of the set of patterns to produce a shifted representation of the first pattern;
comparing the shifted representation of the first pattern with the second pattern representation;
determining, based on the comparison results the shifted representation and the second pattern representation, whether the first pattern and the second pattern are shifted with respect to each other; and
responsive to the patterns being the shifted, grouping the first pattern and the second pattern in a second group characterizing a shifted pattern matching.
   9. The medium of clause 8, wherein determining whether the first pattern and the second pattern are shifted with respect to each other is based on a first element and/or a last element in the comparison results.
   10. The medium of clause 9, shifting comprises:
comparing a first component of the shifted representation and a first component of the second pattern representation to determine a type of first non-intersected feature portions in the respective pattern representations; and
responsive to the first components being different, moving the first pattern with respect to the second pattern until the first components match.
   11. The medium of clause 1, wherein the grouping comprises: determining a fuzzy pattern matching based on a comparison between the pattern representations of the set of patterns.
   12. The medium of clause 11, wherein grouping comprises:
comparing a first pattern representation associated with a first pattern of the set of patterns with a second pattern representation associated with the second pattern of the set of patterns;
determining, based on the comparison, whether characteristics of the first pattern and the second pattern within a desired tolerance limit; and
responsive to the first pattern representation and the second pattern representation being within the tolerance limit, grouping the first pattern and the second pattern in a third group characterizing the fuzzy pattern matching.
   13. The medium of clause 12, wherein grouping the first pattern and the second pattern:
computing a difference representation between the first pattern representation and the second pattern representation;
determining whether the first components of the difference representation are same, and values of the second components of the difference representation are within a desired tolerance limit;
and responsive to the difference representation being within the desired tolerance limit, grouping the first pattern and the second pattern in the third group characterizing the fuzzy pattern matching.
   14. The medium of clause 1, wherein the grouping comprises:
shifting one pattern with respect to another pattern of the set of patterns; and
determining a fuzzy pattern matching based on a comparison between pattern representations of the shifted pattern and the another pattern.
   15. The medium of clause 14, wherein grouping comprises:
shifting a first pattern of the set of patterns with respect to a second pattern of the set of patterns to produce a shifted representation of the first pattern;
comparing the shifted representation of the first pattern with the second pattern representation;
determining, based on the comparison results of the shifted representation and the second pattern representation, whether the first pattern and the second pattern are shifted with respect to each other, and whether the comparison results are within a desired tolerance; and
responsive to the comparison results indicating shifted patterns and within the desired tolerance, grouping the first pattern and the second pattern in a fourth group characterizing a shifted pattern with fuzzy matching.
   16. The medium of clause 1, wherein one or more patterns of the set of patterns comprises a vertex portion.
   17. The medium of clause 16, wherein obtaining the set of pattern comprises:
determining one or more non-intersected feature portion candidates within the vertex portion.
   18. The medium of clause 17, wherein grouping the vertex portions comprises:
comparing pattern representations of the one or more non-intersected feature portion candidates with the pattern representations of the set of patterns; and
grouping, based on the comparison, the vertex pattern into one or more groups.
   19. The medium of clause 17, wherein determining the non-intersected feature pattern candidates comprises:
defining an adjustable bounding box; and
partitioning, using the adjustable bounding box, portions of the vertex pattern into one or more non-intersected feature portions.
   20. The medium of clause 19, further comprising:
adjusting a size of the adjustable bounding box such that a maximum area having the non-intersected feature portion within the vertex portion is covered.
   21. The medium of clause 1, wherein the set of patterns comprises:
parallel non-intersected feature portions;
horizontal non-intersected feature portions;
vertical non-intersected feature portions; and/or
inclined non-intersected feature portions, wherein a feature portion is inclined with respect to the designated edge.
   22. The medium of clause 21, wherein, for the horizontal or the vertical non-intersected feature portions, the projected refers to intersection of the non-intersected feature portion with the designated edge.
   23. The medium of clause 21, wherein, for the inclined non-intersected feature portions, the projected refers to intersection of the inclined non-intersected feature portion with an extended portion of the designated edge.
   24. The medium of clause 21, further comprising:
obtaining the set of patterns further comprising one or more inclined patterns comprising the inclined non-intersected feature portions within a bounding box of an inclined pattern; and
encoding each of the inclined patterns to the pattern representation having a first element set and a second element set, wherein the first element set correspond to the designated edge and a second element set correspond to another edge different from the designated edge of the bounding box of the inclined pattern.
   25. The medium of clause 24, wherein the encoding comprises:
projecting the inclined non-intersected feature portions of the inclined pattern along an extended designated edge of the bounding box; and
encoding the projected inclined non-intersected feature portions into elements, each element comprising a first component and a second component.
   26. The medium of clause 1, wherein each pattern of the set of patterns are represented an image associated with a patterning process.
   27. The medium of clause 26, wherein the image corresponds to a design layout image, a mask image, an aerial image, an etch image, or a metrology image.
   28. The medium of clause 26, wherein the image is a binary image, wherein a bar is represented in a first color and a space is presented in a second color.
   29. The medium of clause 1, wherein each pattern of the set of patterns are represented as contours associated with a patterning process.
   30. The medium of clause 28, wherein the contours correspond to contours extracted from a design layout, a mask image, an aerial image, an etch image, or a metrology image.
   31. The medium of clause 1, wherein the individual non-intersected feature portion comprises: a bar or a space, and the pattern comprises one or more bars and one or more spaces.
   32. The medium of clause 1, wherein the pattern representation is a vector, and the first component of the vector is a first digit characterizing a type of the feature portion, and the second component of the vector is a second digit characterizing a width.
   33. The medium of clause 1, wherein the type of an individual non-intersected feature portion is represented by a white or black color.
   34. A method for grouping patterns associated with one or more design layouts of a semiconductor, the method comprising:
obtaining a set of patterns of one or more design layouts, a pattern of the set of patterns comprising a non-intersected feature portion within a bounding box of the pattern;
encoding a non-intersected feature portion of a pattern of the set of patterns to a pattern representation having elements, each element comprising a first component indicating a type of an individual non-intersected feature portion, and a second component indicating a width of the individual non-intersected feature portion projected along a designated edge of an area enclosing the pattern; and
grouping the set of patterns into one or more groups by comparing the pattern representations associated the set of patterns.
   35. The method of clause 34, further comprising:

selecting a representative pattern from each group of the one or more groups for metrology measurements, or training models related to lithographic process.

36. The method of clause 34, wherein obtaining the set of patterns comprises:
obtaining a first set of patterns of the one or more design layouts; and
selecting, from the one or more design layouts, a second set of patterns based on the first set of patterns, each pattern of the second set of patterns including an additional area around a corresponding pattern of the first set of patterns.
   37. The method of clause 36, wherein the set of patterns comprises: the first set of patterns of the one or more design layouts, the second set of patterns, or a combination thereof.
   38. The method of clause 34, wherein the grouping comprises: determining an exact pattern matching based on a comparison between the pattern representations of the set of patterns.
   39. The method of clause 38, wherein grouping comprises:
comparing a first pattern representation associated with a first pattern of the set of patterns with a second pattern representation associated with the second pattern of the set of patterns; and
responsive to a determination that the first pattern representation and the second pattern representation being the same, grouping the first pattern and the second pattern in a first group characterizing the exact pattern matching.
   40. The method of clause 34, wherein the grouping comprises: determining a pattern matching by shifting the pattern representations with respect to each other and comparing the shifted pattern representations.
   41. The method of clause 40, wherein grouping comprises:
shifting a first pattern of the set of patterns with respect to a second pattern of the set of patterns to produce a shifted representation of the first pattern;
comparing the shifted representation of the first pattern with the second pattern representation;
determining, based on the comparison results the shifted representation and the second pattern representation, whether the first pattern and the second pattern are shifted with respect to each other; and
responsive to the patterns being the shifted, grouping the first pattern and the second pattern in a second group characterizing a shifted pattern matching.
   42. The method of clause 41, wherein determining whether the first pattern and the second pattern are shifted with respect to each other is based on a first element and/or a last element in the comparison results.
   43. The method of clause 42, shifting comprises:
comparing a first component of the shifted representation and a first component of the second pattern representation to determine a type of first non-intersected feature portions in the respective pattern representations; and
responsive to the first components being different, moving the first pattern with respect to the second pattern until the first components match.
   44. The method of clause 34, wherein the grouping comprises: determining a fuzzy pattern matching based on a comparison between the pattern representations of the set of patterns.
   45. The method of clause 44, wherein grouping comprises:
comparing a first pattern representation associated with a first pattern of the set of patterns with a second pattern representation associated with the second pattern of the set of patterns;
determining, based on the comparison, whether characteristics of the first pattern and the second pattern within a desired tolerance limit; and
responsive to the first pattern representation and the second pattern representation being within the tolerance limit, grouping the first pattern and the second pattern in a third group characterizing the fuzzy pattern matching.
   46. The method of clause 45, wherein grouping the first pattern and the second pattern:
computing a difference representation between the first pattern representation and the second pattern representation;
determining whether the first components of the difference representation are same, and values of the second components of the difference representation are within a desired tolerance limit; and
responsive to the difference representation being within the desired tolerance limit, grouping the first pattern and the second pattern in the third group characterizing the fuzzy pattern matching.
   47. The method of clause 34, wherein the grouping comprises:
shifting one pattern with respect to another pattern of the set of patterns; and
determining a fuzzy pattern matching based on a comparison between pattern representations of the shifted pattern and the another pattern.
   48. The method of clause 47, wherein grouping comprises:
shifting a first pattern of the set of patterns with respect to a second pattern of the set of patterns to produce a shifted representation of the first pattern;
comparing the shifted representation of the first pattern with the second pattern representation;
determining, based on the comparison results of the shifted representation and the second pattern representation, whether the first pattern and the second pattern are shifted with respect to each other, and whether the comparison results are within a desired tolerance; and
responsive to the comparison results indicating shifted patterns and within the desired tolerance, grouping the first pattern and the second pattern in a fourth group characterizing a shifted pattern with fuzzy matching.
   49. The method of clause 34, wherein one or more patterns of the set of patterns comprises a vertex portion.
   50. The method of clause 49, wherein obtaining the set of pattern comprises:
determining one or more non-intersected feature portion candidates within the vertex portion.
   51. The method of clause 50, wherein grouping the vertex portions comprises:
comparing pattern representations of the one or more non-intersected feature portion candidates with the pattern representations of the set of patterns; and
grouping, based on the comparison, the vertex pattern into one or more groups.
   52. The method of clause 50, wherein determining the non-intersected feature pattern candidates comprises:
defining an adjustable bounding box; and
partitioning, using the adjustable bounding box, portions of the vertex pattern into one or more non-intersected feature portions.
   53. The method of clause 52, further comprising:
adjusting a size of the adjustable bounding box such that a maximum area having the non-intersected feature portion within the vertex portion is covered.
   54. The method of clause 34, wherein the set of patterns comprises:
parallel non-intersected feature portions;
horizontal non-intersected feature portions;
vertical non-intersected feature portions; and/or
inclined non-intersected feature portions, wherein a feature portion is inclined with respect to the designated edge.
   55. The method of clause 54, wherein, for the horizontal or the vertical non-intersected feature portions, the projected refers to intersection of the non-intersected feature portion with the designated edge.
   56. The method of clause 54, wherein, for the inclined non-intersected feature portions, the projected refers to intersection of the inclined non-intersected feature portion with an extended portion of the designated edge.
   57. The method of clause 54, further comprising:
obtaining the set of patterns further comprising one or more inclined patterns comprising the inclined non-intersected feature portions within a bounding box of an inclined pattern; and
encoding each of the inclined patterns to the pattern representation having a first element set and a second element set, wherein the first element set correspond to the designated edge and a second element set correspond to another edge different from the designated edge of the bounding box of the inclined pattern.
   58. The method of clause 57, wherein the encoding comprises:
projecting the inclined non-intersected feature portions of the inclined pattern along an extended designated edge of the bounding box; and
encoding the projected inclined non-intersected feature portions into elements, each element comprising a first component and a second component.
   59. The method of clause 34, wherein each pattern of the set of patterns are represented an image associated with a patterning process.
   60. The method of clause 59, wherein the image corresponds to a design layout image, a mask image, an aerial image, an etch image, or a metrology image.
   61. The method of clause 59, wherein the image is a binary image, wherein a bar is represented in a first color and a space is presented in a second color.
   62. The method of clause 34, wherein each pattern of the set of patterns are represented as contours associated with a patterning process.
   63. The method of clause 62, wherein the contours correspond to contours extracted from a design layout, a mask image, an aerial image, an etch image, or a metrology image.
   64. The method of clause 34, wherein the individual non-intersected feature portion comprises: a bar or a space, and the pattern comprises one or more bars and one or more spaces.
   65. The method of clause 34, wherein the pattern representation is a vector, and the first component of the vector is a first digit characterizing a type of the feature portion, and the second component of the vector is a second digit characterizing a width.
   66. The method of clause 34, wherein the type of an individual non-intersected feature portion is represented by a white or black color.

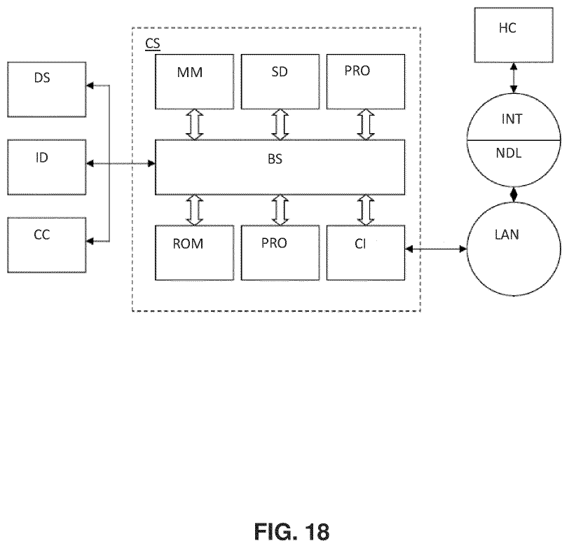

FIG. 18 is a block diagram of an example computer system CS, according to an embodiment. Computer system CS includes a bus BS or other communication mechanism for communicating information, and a processor PRO (or multiple processor) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions to be executed by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the features described herein. Transitory computer-readable media can include a carrier wave or other propagating electromagnetic signal.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) both use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The descriptions above are intended to be illustrative, not limiting. Thus, it will be apparent to one skilled in the art that modifications may be made as described without departing from the scope of the claims set out below.

The invention claimed is:

1. A non-transitory computer-readable medium having instructions recorded thereon or therein, the instructions, when executed by a computer system, configured to cause the computer system to at least:
obtain a set of patterns of one or more design layouts of a semiconductor circuit design, a pattern of the set of patterns comprising a non-intersected feature portion within a bounding box of the pattern;
encode a non-intersected feature portion of a pattern of the set of patterns to a pattern representation having elements, each element comprising a first component indicating a type of an individual non-intersected feature portion, and a second component indicating a width of the individual non-intersected feature portion projected along a designated edge of an area that contains the pattern; and
group the set of patterns into one or more groups by comparing the pattern representations associated with the set of patterns.

2. The medium of claim 1, wherein the instructions, when executed by the computer system, are further configured to cause the computer system to select a representative pattern from each group of the one or more groups for metrology measurement, or for training a model related to a lithographic process.

3. The medium of claim 1, wherein the instructions, when executed by the computer system, configured to cause the computer system to group the set of patterns are further configured to cause the computer system to determine an exact pattern matching or a fuzzy pattern matching based on a comparison between the pattern representations of the set of patterns.

4. The medium of claim 1, wherein the instructions, when executed by the computer system, configured to cause the computer system to group the set of patterns are further configured to cause the computer system to determine a pattern matching by shifting the pattern representations with respect to each other and comparing the shifted pattern representations.

5. The medium of claim 1, wherein the instructions, when executed by the computer system, configured to cause the computer system to group the set of patterns are further configured to cause the computer system to:
compare a first pattern representation associated with a first pattern of the set of patterns with a second pattern representation associated with the second pattern of the set of patterns;
determine, based on the comparison, whether one or more characteristics of the first pattern and the second pattern are within a desired tolerance limit; and
responsive to the first pattern representation and the second pattern representation being within the tolerance limit, group the first pattern and the second pattern in a third group characterizing the fuzzy pattern matching.

6. The medium of claim 1, wherein one or more patterns of the set of patterns comprises a vertex portion.

7. The medium of claim 6, wherein the instructions, when executed by the computer system, configured to cause the computer system to obtain the set of patterns are further configured to cause the computer system to:
determine one or more non-intersected feature portion candidates within the vertex portion;
compare pattern representations of the one or more non-intersected feature portion candidates with the pattern representations of the set of patterns; and
group, based on the comparison, the vertex portion into one or more groups.

8. The medium of claim 7, wherein the instructions, when executed by the computer system, configured to cause the computer system to determine the one or more non-intersected feature pattern candidates are further configured to cause the computer system to:
define an adjustable bounding box;
partition, using the adjustable bounding box, portions of the vertex pattern into one or more non-intersected feature portions; and
adjust a size of the adjustable bounding box such that a maximum area having the one or more non-intersected feature portions within the vertex portion is covered.

9. The medium of claim 1, wherein the set of patterns comprises:
parallel non-intersected feature portions;
horizontal non-intersected feature portions;
vertical non-intersected feature portions; and/or
inclined non-intersected feature portions, wherein a feature portion is inclined with respect to the designated edge.

10. The medium of claim 7, wherein the instructions, when executed by the computer system, are further configured to cause the computer system to:
obtain one or more inclined patterns as the set of patterns, the one or more inclined patterns comprising inclined non-intersected feature portions within a bounding box of an inclined pattern; and
encode each of the one or more inclined patterns to a pattern representation having a first element set and a second element set, wherein the first element set corresponds to the designated edge and a second element set corresponds to another edge different from the designated edge of the bounding box of the inclined pattern.

11. The medium of claim 8, wherein the instructions, when executed by the computer system, configured to cause the computer system to encode each of the one or more inclined patterns are further configured to cause the computer system to:
project one or more the inclined non-intersected feature portions of an inclined pattern along an extended designated edge of the bounding box; and
encode the projected one or more inclined non-intersected feature portions into elements, each element comprising a first component and a second component.

12. The medium of claim 1, wherein each pattern of the set of patterns are represented as an image associated with a patterning process,
wherein the image corresponds to a design layout image, a mask image, an aerial image, an etch image, a binary image or a metrology image.

13. The medium of claim 1, wherein each pattern of the set of patterns are represented as a contour associated with a patterning process,
wherein the contour corresponds to a contour extracted from a design layout, a mask image, an aerial image, an etch image, or a metrology image.

14. The medium of claim 1, wherein the individual non-intersected feature portion comprises: a bar or a space, and the pattern comprises one or more bars and one or more spaces.

15. The medium of claim 1, wherein the pattern representation is a vector, and the first component of the vector is a first digit characterizing a type of the feature portion, and the second component of the vector is a second digit characterizing a width.

16. A method comprising:
obtaining a set of patterns of one or more design layouts of a semiconductor circuit design, a pattern of the set of patterns comprising a non-intersected feature portion within a bounding box of the pattern;
encoding a non-intersected feature portion of a pattern of the set of patterns to a pattern representation having elements, each element comprising a first component indicating a type of an individual non-intersected feature portion, and a second component indicating a width of the individual non-intersected feature portion projected along a designated edge of an area enclosing the pattern; and
grouping, by a hardware computer, the set of patterns into one or more groups by comparing the pattern representations associated with the set of patterns.

17. The method of claim 16, further comprising selecting a representative pattern from each group of the one or more groups for metrology measurement, or for training a model related to a lithographic process.

18. The method of claim 16, wherein the grouping comprises determining an exact pattern matching or a fuzzy pattern matching based on a comparison between the pattern representations of the set of patterns.

19. The method of claim 16, wherein the grouping comprises:
comparing a first pattern representation associated with a first pattern of the set of patterns with a second pattern representation associated with the second pattern of the set of patterns;
determining, based on the comparison, whether one or more characteristics of the first pattern and the second pattern are within a desired tolerance limit; and
responsive to the first pattern representation and the second pattern representation being within the tolerance limit, grouping the first pattern and the second pattern in a group characterizing the fuzzy pattern matching.

20. The method of claim 16, wherein one or more patterns of the set of patterns comprises a vertex portion and the obtaining the set of patterns comprises:
determining one or more non-intersected feature portion candidates within the vertex portion;
comparing pattern representations of the one or more non-intersected feature portion candidates with the pattern representations of the set of patterns; and
grouping, based on the comparison, the vertex portion into one or more groups.
